(19) United States
(12) Patent Application Publication
(10) Pub. No.: US 2023/0036430 A1
(43) Pub. Date: Feb. 2, 2023

(54) BONDING STRUCTURE, SEMICONDUCTOR DEVICE, AND BONDING STRUCTURE FORMATION METHOD

(71) Applicant: ROHM CO., LTD., Kyoto-shi (JP)

(72) Inventor: Kazunori FUJI, Kyoto-shi (JP)

(21) Appl. No.: 17/964,584

(22) Filed: Oct. 12, 2022

Related U.S. Application Data
(63) Continuation of application No. 17/273,210, filed on Mar. 3, 2021.

(30) Foreign Application Priority Data
Sep. 7, 2018 (JP) 2018-167642

(51) Int. Cl. H01L 23/00; H01L 23/495

(52) U.S. Cl. CPC H01L 24/32; H01L 23/49513; H01L 24/83; H01L 23/49575; H01L 23/49582; H01L 24/29; H01L 2224/29139; H01L 2224/3207; H01L 2224/83039; H01L 2224/83192; H01L 2224/83385; H01L 2224/8384; H01L 2924/35121

(57) ABSTRACT

A bonded structure includes a semiconductor element, an electrical conductor and a sintered metal layer. The semiconductor element has an element obverse surface and an element reverse surface spaced apart from each other in a first direction and includes a reverse-surface electrode on the element reverse surface. The electrical conductor has a mount surface facing in a same direction as the element obverse surface and supports the semiconductor element with the mount surface facing the element reverse surface. The sintered metal layer bonds the semiconductor element to the electrical conductor and electrically connects the reverse-surface electrode and the electrical conductor. The mount surface includes a roughened area roughened by a roughening process. The sintered metal layer is formed on the roughened area.

### TECHNICAL FIELD

The present disclosure relates to a bonded structure including a semiconductor element and an electrical conductor, a semiconductor device including such a bonded structure, and a method for forming such a bonded structure.

### BACKGROUND ART

Conventionally, lead solder has been used as a convenient bonding material for bonding a semiconductor element to an electrical conductor. Lead solder, however, is being replaced by lead-free bonding materials for the purpose of human health protection and environmental load reduction. For example, Patent Document 1 discloses a semiconductor device in which a sintered metal is used as a bonding material. The semiconductor device disclosed in the document includes a semiconductor element (Si chip), an electrical conductor (lead frame), a bonding material (sintered layer) and a sealing resin (epoxy resin). The electrical conductor is made of, for example, a metal containing copper and has a die-pad portion. The semiconductor element is electrically bonded to the die-pad portion by the bonding material. The bonding material is made of sintered silver, for example. The sealing resin covers the semiconductor element, the bonding material and a part of the electrical conductor.

### PRIOR ART DOCUMENT

### Patent Document

Patent Document 1: JP-A-2011-249257

### SUMMARY OF THE INVENTION

### Problem to be Solved by the Invention

The semiconductor element of a semiconductor device generates heat when electric current is passed to the semiconductor element. The semiconductor element and the electrical conductor have different thermal expansion coefficients and thus apply thermal stress to the bonding material when heated. Solder is more ductile than sintered metals. When solder is used as a bonding material, it works as a buffer to mitigate the thermal stress. When a sintered metal is used as a bonding material, it does not work much to mitigate the thermal stress, and a relatively large load is imposed. As a result, peeling or failure (such as rupturing) of the bonding material may occur at the bonded interface between the bonding material and the semiconductor element or at the bonded interface between the bonding material and the electrical conductor. Peeling or failure of the bonding material will impair the electrical conductivity and heat dispersion of the semiconductor device.

The present disclosure has been conceived in view of the problems noted above and aims to provide a bonded structure that improves thermal stability. The present disclosure also aims to provide a semiconductor device having such a bonded structure and a method for forming such a bonded structure.

### Means to Solve the Problem

A first aspect of the present disclosure provides a bonded structure that includes: a semiconductor element having an element obverse surface and an element reverse surface spaced apart from each other in a first direction, where the semiconductor element includes a reverse-surface electrode on the element reverse surface; an electrical conductor having a mount surface facing in a same direction as the element obverse surface and supporting the semiconductor element with the mount surface facing the element reverse surface; and a sintered metal layer that bonds the semiconductor element to the electrical conductor and electrically connects the reverse-surface electrode and the electrical conductor. The mount surface includes a roughened area roughened by a roughening process. The sintered metal layer is formed on the roughened area.

In a preferred embodiment of the bonded structure, the roughened area includes a recess that is recessed in the first direction from the mount surface.

In a preferred embodiment of the bonded structure, the recess includes a plurality of first trenches. The plurality of first trenches as viewed in the first direction extend in a second direction perpendicular to the first direction and are arranged next to each other in a third direction perpendicular to the first direction and the second direction.

In a preferred embodiment of the bonded structure, the recess further includes a plurality of second trenches. The plurality of second trenches as viewed in the first direction extend in the third direction and are arranged next to each other in the second direction. As viewed in the first direction, the plurality of second trenches intersect the plurality of first trenches.

In a preferred embodiment of the bonded structure, as viewed in the first direction, each of the plurality of first trenches extends linearly in the second direction. As viewed in the first direction, each of the plurality of second trenches extends linearly in the third direction.

In a preferred embodiment of the bonded structure, as viewed in the first direction, the plurality of first trenches and the plurality of second trenches are substantially orthogonal to each other.

In a preferred embodiment of the bonded structure, the roughened area includes an intersecting portion and a non-intersecting portion. The intersecting portion overlaps with one of the plurality of first trenches and also with one of the plurality of second trenches as viewed in the first direction. The non-intersecting portion overlaps with only one trench out of the plurality of first and second trenches as viewed in the first direction. A dimension of the intersecting portion in the first direction is larger than a dimension of the non-intersecting portion in the first direction.

In a preferred embodiment of the bonded structure, the recess has finer surface asperities than asperities provided by the recess.

In a preferred embodiment of the bonded structure, the roughened area is coated with silver plating.

In a preferred embodiment of the bonded structure, the semiconductor element has an element side surface connected at an edge in the first direction to the element obverse surface and at another edge in the first direction to the element reverse surface. The sintered metal layer includes a fillet covering a part of the element side surface along the edge connected to the element reverse surface.

In a preferred embodiment of the bonded structure, the sintered metal layer is made of sintered silver.

In a preferred embodiment of the bonded structure, the electrical conductor is made of a copper-containing material.

A second aspect of the present disclosure provides a semiconductor device including the bonded structure in accordance with the first aspect. The semiconductor device includes: a first switching element as the semiconductor element; a first conductive member as the electrical conductor supporting the first switching element; a first bonding layer as the sintered metal layer electrically bonding the first switching element and the first conductive member; and a sealing resin covering the first switching element, the first bonding layer and at least a part of the first conductive member. The first conductive member includes a first area as the roughened area. As viewed in the first direction, the first area overlaps with the first bonding layer.

In a preferred embodiment, the semiconductor device further includes a first terminal and a second terminal each of which is electrically connected to the first switching element. The first terminal is bonded to the first conductive member and electrically connected to the first switching element via the first conductive member.

In a preferred embodiment of the semiconductor device, the first terminal includes a first terminal portion exposed from the sealing resin. The second terminal includes a second terminal portion exposed from the sealing resin.

In a preferred embodiment, the semiconductor device further includes: a second switching element as the semiconductor element different from the first switching element; a second conductive member as the electrical conductor supporting the second switching element; and a second bonding layer as the sintered metal layer electrically bonding the second switching element and the second conductive member. The sealing resin also covers the second switching element, the second bonding layer and at least a part of the second conductive member. The second conductive member includes a second area as the roughened area. As viewed in the first direction, the second area overlaps with the second bonding layer.

In a preferred embodiment, the semiconductor device further includes a third terminal electrically connected to the second switching element. The third terminal is bonded to the second conductive member and electrically connected to the second switching element via the second conductive member. The second switching element is electrically connected to the first conductive member.

In a preferred embodiment of the semiconductor device, the third terminal includes a third terminal portion exposed from the sealing resin.

In a preferred embodiment, the semiconductor device further includes an insulating member disposed between the second terminal portion and the third terminal portion in the first direction. A part of the insulating member overlaps with the second terminal portion and the third terminal portion as viewed in the first direction.

A third aspect of the present disclosure provides a method for forming a bonded structure that includes: a semiconductor element having an element obverse surface and an element reverse surface spaced apart from each other in a first direction, the semiconductor element including a reverse-surface electrode on the element reverse surface; an electrical conductor having a mount surface facing in a same direction as the element obverse surface and supporting the semiconductor element with the mount surface facing the element reverse surface; and a sintered metal layer that bonds the semiconductor element to the electrical conductor and electrically connects the reverse-surface electrode and the electrical conductor. The method includes: a process of preparing the electrical conductor; a roughening process of forming a roughened area on at least a part of the mount surface; a paste application process of applying a metal paste for sintering on at least a part of the roughened area; a mounting process of placing the semiconductor element on the metal paste, with the element reverse surface facing the mount surface; and a sintering process of thermally treating the metal paste to form the sintered metal layer.

According to a preferred embodiment of the method, the roughening process includes forming the roughened area by irradiating the mount surface with a laser beam.

### Advantages of the Invention

The bonded structure and the semiconductor device according to the present disclosure can improve thermal stability. The method of forming according to the present invention enables the production of such a bonded structure.

### BRIEF DESCRIPTION OF THE DRAWINGS

FIG. 1 is a plan view of a bonded structure according to a first embodiment.

FIG. 2 is a sectional view taken along line II-II of FIG. 1.

FIG. 3 is an enlarged plan view showing area III of FIG. 1.

FIG. 4 is a sectional view taken along line IV-IV of FIG. 3.

FIG. 5 is a sectional view taken along line V-V of FIG. 3.

FIG. 6 is a schematic view of an example of a laser emitting device.

FIG. 7 is a view of a laser irradiation pattern according to the first embodiment.

FIG. 8 is a schematic sectional view of a bonded structure according to the first embodiment, showing a sintered metal layer after heat cycle testing.

FIG. 9 is a schematic sectional view of a conventional bonded structure, showing a sintered metal layer after heat cycle testing.

FIG. 10 is a plan view of a bonded structure (shown without a semiconductor element and a sintered metal layer) according to a second embodiment.

FIG. 11 is an enlarged plan view showing area XI of FIG. 10.

FIG. 12 is a sectional view taken along line XII-XII of FIG. 11.

FIG. 13 is a plan view of a bonded structure (shown without a semiconductor element and a sintered metal layer) according to a third embodiment.

FIG. 14 is an enlarged plan view showing area XIV of FIG. 13.

FIG. 15 is a sectional view taken along line XV-XV of FIG. 14.

FIG. 16 is a plan view of a bonded structure (shown without a semiconductor element and a sintered metal layer) according to a fourth embodiment.

FIG. 17 is an enlarged plan view showing area XVII of FIG. 16.

FIG. 18 is a sectional view taken along line XVIII-XVIII of FIG. 17.

FIG. 19 is a plan view of a bonded structure (shown without a semiconductor element and a sintered metal layer) according to a fifth embodiment.

FIG. 20 is an enlarged plan view showing area XX of FIG. 19.

FIG. 21 is a sectional view taken along line XXI-XXI of FIG. 20.

FIG. 22 is a sectional view of a bonded structure according to a variation.

FIG. 23 is a perspective view of a semiconductor device.

FIG. 24 is a perspective view similar to FIG. 23, but omitting a sealing resin.

FIG. 25 is a plan view of the semiconductor device.

FIG. 26 is a perspective view similar to FIG. 25, but showing the sealing resin in phantom.

FIG. 27 is an enlarged view showing a part of FIG. 26.

FIG. 28 is a front view of the semiconductor device.

FIG. 29 is a bottom view of the semiconductor device.

FIG. 30 is a left-side view of the semiconductor device.

FIG. 31 is a right-side view of the semiconductor device.

FIG. 32 is a sectional view taken along line XXXII-XXXII of FIG. 26.

FIG. 33 is a sectional view taken along line XXXIII-XXXIII of FIG. 26.

FIG. 34 is a sectional view showing an essential part of FIG. 33.

FIG. 35 is a plan view of an example of a weld mark.

FIG. 36 is a perspective view of a semiconductor device according to another embodiment.

FIG. 37 is a perspective view of a semiconductor device according to a yet another embodiment.

FIG. 38 is a perspective view of a semiconductor device according to a yet another embodiment.

### MODE FOR CARRYING OUT THE INVENTION

With reference to the accompanying drawings, the following describes embodiments of a bonded structure, a semiconductor device, and a method for forming a bonded structure according to the present disclosure.

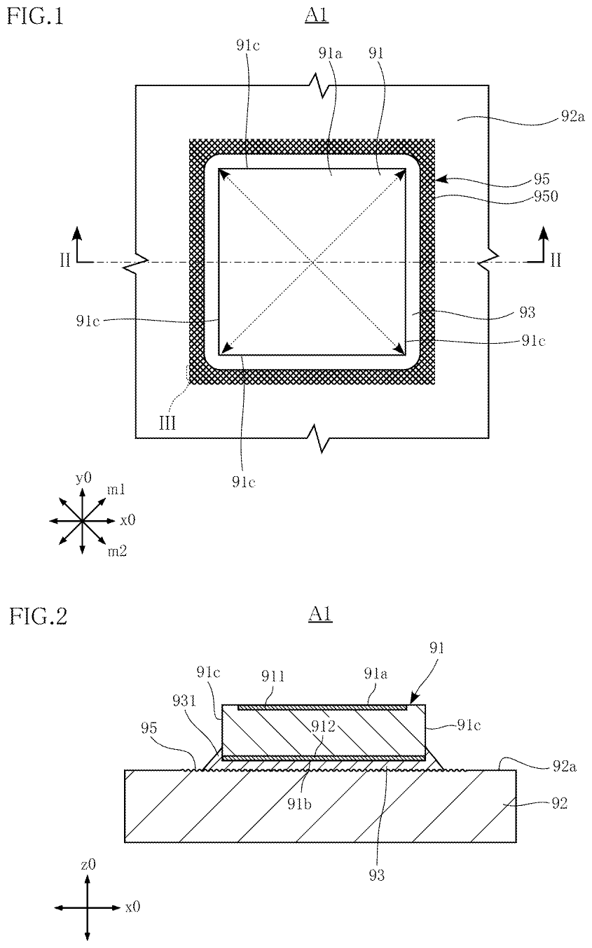

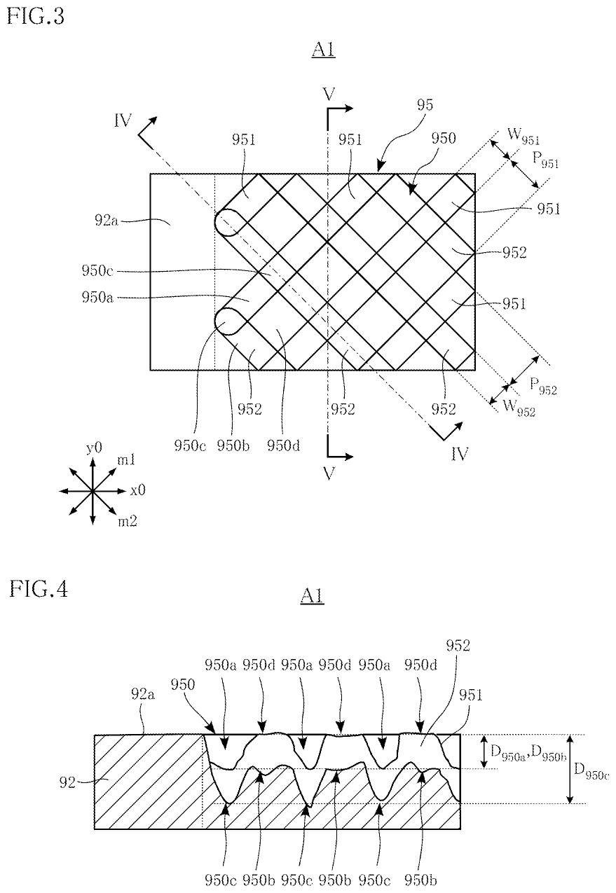

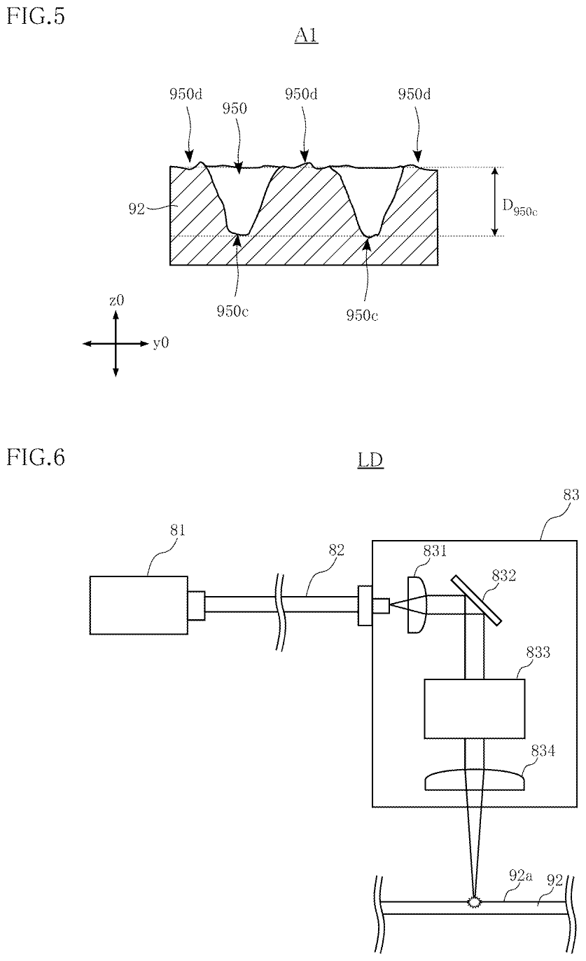

First, a bonded structure according to a first embodiment of the present disclosure will be described with reference to FIGS. 1 to 5. A bonded structure A1 according to the first embodiment includes a semiconductor element 91, an electrical conductor 92 and a sintered metal layer 93. FIG. 1 is a plan view of the bonded structure A1. FIG. 2 is a sectional view taken along line II-II of FIG. 1. FIG. 3 is an enlarged plan view showing area III of FIG. 1. FIG. 4 is a sectional view taken along line IV-IV of FIG. 3. FIG. 5 is a sectional view taken along line V-V of FIG. 3.

For convenience, FIGS. 1 to 5 define three mutually perpendicular directions as first-axis direction z0, a second-axis direction x0 and a third-axis direction y0. The first-axis direction z0 corresponds to the thickness direction of the bonded structure A1. The second-axis direction x0 corresponds to the horizontal direction as seen in the plan view of the bonded structure A1 (see FIG. 1). The third-axis direction y0 corresponds to the vertical direction as seen in the plan view of the bonded structure A1 (see FIG. 1).

The semiconductor element 91 is made of a semiconductor material. Suitable semiconductor materials for the semiconductor element 91 include, but not limited to, silicon (Si), silicon carbide (SiC), gallium arsenide (GaAs) and gallium nitride (GaN). The semiconductor element 91 may be, but not limited to, a transistor, a diode, a resistor, a capacitor or an integrated circuit (IC). The semiconductor element 91 may be substantially rectangular, and typically substantially square, as viewed in the first-axis direction z0. For convenience, two directions orthogonal to the first-axis direction z0 are defined as orthogonal directions m1 and m2. As viewed in the first-axis direction z0, the orthogonal direction m1 is rotated 45° counterclockwise from the second-axis direction x0, and the orthogonal direction m2 is rotated 45° clockwise from the second-axis direction x0. The orthogonal direction m1 and the orthogonal direction m2 are orthogonal to each other. In the present embodiment, the semiconductor element 91 is substantially square as viewed in the first-axis direction z0. Thus, the orthogonal directions m1 and m2 coincide with the directions of the two diagonal lines of the semiconductor element 91 as viewed in the first-axis direction z0. Note that the directions of the two diagonal lines of the semiconductor element 91 as viewed in the first-axis direction may be defined as the orthogonal direction m1 and m2. Per this definition, when the semiconductor element 91 has the shape of a rectangle other than a square as viewed in the first-axis direction z0, the orthogonal directions m1 and m2 are not orthogonal to each other.

As shown in FIGS. 1 and 2, the semiconductor element 91 has an element obverse surface 91a, an element reverse surface 91b and a plurality of element side surfaces 91c. The element obverse surface 91a and the element reverse surface 91b are spaced apart and face away from each other in the first-axis direction z0. The element obverse surface 91a and the element reverse surface 91b are substantially flat. Each element side surface 91c is connected to the element obverse surface 91a at one edge in the first-axis direction z0 and also to the element reverse surface 91b at the other edge in the first-axis direction z0. The element side surfaces 91c are substantially perpendicular to the element obverse surface 91a and the element reverse surface 91b. The element side surfaces 91c of the semiconductor element 91 include a pair of element side surfaces 91c spaced apart and face away from each other in the second-axis direction x0, and a pair of element side surfaces 91c spaced apart and face away from each other in the third-axis direction y0.

As shown in FIG. 2, the semiconductor element 91 includes an obverse-surface electrode 911 and a reverse-surface electrode 912. The obverse-surface electrode 911 and the reverse-surface electrode 912 comprise terminals of the semiconductor element 91. The obverse-surface electrode 911 is exposed on the element obverse surface 91a. The obverse-surface electrode 911 is a component to which a bonding wire or a lead may be connected. The reverse-surface electrode 912 is exposed on the element reverse surface 91b. The reverse-surface electrode 912 overlaps with most of the element reverse surface 91b as viewed in the first-axis direction z0. The reverse-surface electrode 912 is electrically connected to the electrical conductor 92 via the sintered metal layer 93.

The electrical conductor 92 supports the semiconductor element 91. The electrical conductor 92 is a metal plate, for example. The metal plate is made of copper (Cu) or a Cu alloy, for example. The dimension of the electrical conductor 92 in the first-axis direction z0 (thickness) may be, but not limited to, about 0.4 to 3 mm, for example. The electrical conductor 92 has a mount surface 92a on which the semiconductor element 91 is mounted. The mount surface 92a faces one side in the first-axis direction z0 (in this embodiment, upward as seen in FIG. 2). The mount surface 92a faces the element reverse surface 91b of the semiconductor element 91.

The sintered metal layer 93 is disposed between the semiconductor element 91 and the electrical conductor 92 to bond the semiconductor element 91 and the electrical conductor 92. That is, the semiconductor element 91 is fixed to the electrical conductor 92 by the sintered metal layer 93. The dimension of the sintered metal layer 93 in the first-axis direction z0 may be, for example, about 30 to 120 μm at a part between the semiconductor element 91 and the electrical conductor 92.

The sintered metal layer 93 is made of a sintered metal obtained by sintering. The sintered metal that forms the sintered metal layer 93 may be, but not limited to, sintered silver. Other examples of sintered metals include sintered copper. The sintered metal layer 93 is porous with a number of fine pores. The sintered metal layer 93 of this embodiment has fine open pores. In another embodiment, however, the fine pores may be filled with an epoxy resin, for example. That is, the sintered metal layer 93 may contain an epoxy resin. Note, however, the sintered metal layer 93 containing too much epoxy resin may suffer from a decrease in electrical conductivity. The amount of epoxy resin can therefore be adjusted in view of the amount of electric current to be supplied to the semiconductor element 91. These may depend on the composition of a metal paste 930 for sintering used in a sintering process, which will be described later.

The sintered metal layer 93 includes a part forming a fillet 931. The fillet 931 extends from the element reverse surface 91b to the element side surfaces 91c. That is, the fillet 931 covers the edge of each element side surface 91c connected to the element reverse surface 91b. Parts of the fillet 931 located at the opposite sides of the semiconductor element 91 in the second-axis directions x0 overlap with parts of the element side surfaces 91c facing in the second-axis direction x0. Similarly, parts of the fillet 931 located at the opposite sides of the semiconductor element 91 in the third-axis direction y0 overlap with parts of the element side surfaces 91c facing in the third-axis direction y0. Note, however, that the sintered metal layer 93 may be without the fillet 931.

The bonded structure A1 includes a roughened area 95 formed on the mount surface 92a of the electrical conductor 92. The roughened area 95 is formed by roughening an area of the mount surface 92a of the electrical conductor 92. In one example, the roughening process is performed by directing a laser beam onto the mount surface 92a of the electrical conductor 92. That is, the roughened area 95 is formed by laser irradiation. The roughened area 95 is rougher than areas of the mount surface 92a not subjected to the roughening process.

The roughened area 95 has recesses 950 formed by laser irradiation. The recesses 950 are recessed from the mount surface 92a in the first-axis direction z0. The recesses 950 have surfaces provided with fine asperities (not shown). The surface asperities provided on the recesses 950 are finer than the asperities provided by the recesses 950. The surfaces of the recesses 950 have a roughness Ra (by arithmetical mean) of about 0.5 to 3.0 μm, for example. Since the recesses 950 are formed by laser irradiation as mentioned above, weld marks (such as weld beads) are formed on their surfaces. Although the weld marks are not shown in FIGS. 1 to 5, at least some of the asperities are provided by the weld marks. The recesses 950 are formed in a predetermined pattern as viewed in the first-axis direction z0. In one example, the recesses 950 are formed in a grid pattern as viewed in the first-axis direction z0. The pattern of the recesses 950 may be changed according to a later-described irradiation pattern of a laser beam. The recesses 950 include a plurality of first elongated trenches 951 and a plurality of second elongated trenches 952.

As shown in FIG. 3, the first elongated trenches 951 as viewed in the first-axis direction z0 extend linearly in the orthogonal direction m1. In the orthogonal direction m2, the first elongated trenches 951 have a dimension (line width) W₉₅₁ (see FIG. 3) of about 4 to 20 μm, for example. As viewed in the first-axis direction z0, the first elongated trenches 951 are parallel to each other in the orthogonal direction m2 at equal distances. The distance P₉₅₁ (see FIG. 3) between each two adjacent first elongated trenches 951 in the orthogonal direction m2 is about 4 to 40 μm, for example. However, the distance P₉₅₁ between each two adjacent first elongated trenches 951 is not required to be all equal. In addition, the line width W₉₅₁ and the distance P₉₅₁ may or may not be equal to each other.

As shown in FIG. 3, the second elongated trenches 952 as viewed in the first-axis direction z0 extend linearly in the orthogonal direction m2. In the orthogonal direction m1, the second elongated trenches 952 have a dimension (line width) W₉₅₂ (see FIG. 3) of about 4 to 20 μm, for example. As viewed in the first-axis direction z0, the second elongated trenches 952 are parallel to each other in the orthogonal direction m1 at equal distances. The distance P₉₅₂ (see FIG. 3) between each two adjacent second elongated trenches 952 in the orthogonal direction m1 is about 4 to 40 μm, for example. However, the distance P₉₅₂ between each two adjacent second elongated trenches 952 is not required to be all equal. In addition, the line width W₉₅₂ and the distance P₉₅₂ may or may not be equal to each other.

As viewed in the first-axis direction z0, each first elongated trench 951 intersects each second elongated trench 952. In the present embodiment, the orthogonal directions m1 and m2 are substantially orthogonal to each other. Thus, the first elongated trenches 951 and the second elongated trenches 952 intersect with each other substantially at right angles.

As shown in FIGS. 3 to 5, the recesses 950 include trench-first portions 950a, trench-second portions 950b, trench-third portions 950c and flat portions 950d. As viewed in the first-axis direction z0, each trench-first portion 950a overlaps with a first elongated trench 951 but not with any second elongated trench 952. As viewed in the first-axis direction z0, each trench-second portion 950b overlaps with a second elongated trench 952 but not with any first elongated trench 951. Each trench-third portion 950c overlaps with both a first elongated trench 951 and a second elongated trench 952. Each flat portion 950d overlaps with none of the first elongated trenches 951 and the second elongated trenches 952. The flat portions 950d have been affected by heat generated by a laser beam applied to form the first elongated trenches 951 and the second elongated trenches 952, so that each flat portion 950d has an uneven surface in the first-axis direction z0 and thus has a rougher surface than the mount surface 92a.

The dimension (depth) D₉₅₀ₐ (see FIG. 4) of the trench-first portions 950a in the first-axis direction z0 is substantially equal to the dimension (depth) D_{950b} (see FIG. 4) of the trench-second portions 950b in the first-axis direction z0. Alternatively, the depth D₉₅₀ₐ of the trench-first portions 950a may be different from the depth D_{950b} of the trench-second portions 950b. The dimension (depth) D_{950c} (see FIG. 4) of the trench-third portions 950c in the first-axis direction z0 is greater than either of the depth D₉₅₀ₐ of the trench-first portions 950a and the depth D_{950b} of the trench-second portions 950b. The depth D_{950c} of the trench-third portions 950c is about 11.06 μm, for example, whereas the depth D₉₅₀ₐ of the trench-first portion 950a and the depth D_{950b} of the trench-second portions 950b are about 5.94 μm, for example. Note that the depths D₉₅₀ₐ, D_{950b} and D_{950c} are not limited to the values mentioned above. The flat portions 950d are substantially flush with the mount surface 92a in the first-axis direction z0.

In the bonded structure A1, the sintered metal layer 93 is formed on the roughened area 95 as shown in FIG. 2. The sintered metal layer 93 is in contact with a region of the roughened area 95, and the recesses 950 (the first elongated trenches 951 and the second elongated trenches 952) located in the area are filled with the sintered metal 93.

The first elongated trenches 951 and the second elongated trenches 952 of the roughened area 95 have a surface oxide layer (not shown). The oxide layer is formed by oxidizing the base material of the electrical conductor 92. That is, the regions of the electrical conductor 92 once melted by a laser beam will have a surface layer made of an oxide of the base material of the electrical conductor 92. The present inventor analyzed the surface of the electrical conductor 92 and confirmed that an anticorrosive component (such as benzotriazole) was detected from the area of the mount surface 92a other than the roughened area 95 but not from the roughened area 95. Although not specifically limited, the thickness of the oxide layer may be about 20 nm, for example.

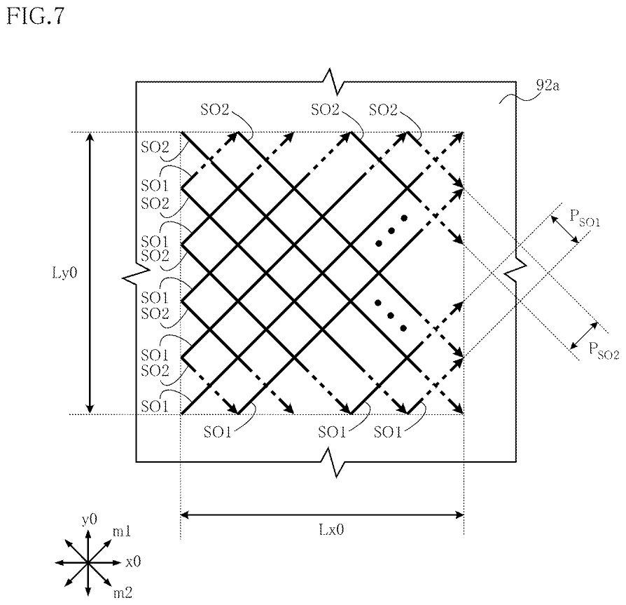

Next, a method for forming a bonded structure A1 according to the first embodiment of the present disclosure will be described with reference to FIGS. 6 and 7.

First, an electrical conductor 92 having a mount surface 92a is prepared. For example, a metal plate made of Cu or a Cu alloy is prepared as the electrical conductor 92. The metal plate is not required to have any specific thickness.

Next, at least a part of the mount surface 92a of the electrical conductor 92 is roughened to form a roughened area 95 on the mount surface 92a. The roughened area 95 is formed to be larger than the semiconductor element 91 as viewed in the first-axis direction z0. The process of roughening a part of the mount surface 92a (the roughening process) involves directing a laser beam onto the mount surface 92a. As a result, holes are formed at regions impinged on by the laser beam. Upon impingement of the laser beam, the energy of the laser beam is converted into heat, which sublimates and melts the impinged regions. When the melted regions solidify again, fine surface asperities are formed as described above. The laser irradiation process may be performed by using a laser emitting device LD (see FIG. 6) described below.

FIG. 6 shows an example of the laser emitting device LD. As shown in FIG. 6, the laser emitting device LD includes a laser oscillator 81, an optical fiber 82 and a laser head 83. The laser oscillator 81 emits a laser beam. In the present embodiment, the laser oscillator 81 emits a YAG laser beam. The YAG laser beam is a green laser. The laser oscillator 81 is not limited to the one that emits the laser beam mentioned above. The optical fiber 82 transmits the laser beam emitted by the laser oscillator 81. The laser head 83 is used to direct the laser beam output from the optical fiber 82 to the target (the electrical conductor 92).

As shown in FIG. 6, the laser head 83 includes a collimating lens 831, a mirror 832, a galvano scanner 833 and a condensing lens 834. The collimating lens 831 collimates a laser beam output from the optical fiber 82 (into parallel rays). The mirror 832 reflects the laser beam collimated by the collimating lens 831 toward the target (the electrical conductor 92). The galvano scanner 833 is used to steer the laser beam to change the incident position of the laser beam on the target (the electrical conductor 92). The galvano scanner 833 may be a well-known scanner including a pair of movable mirrors (not shown) capable of swinging in two mutually perpendicular directions. The condensing lens 834 collects the laser beam output from the galvano scanner 833 onto the target (the electrical conductor 92).

The roughening process of the present embodiment uses the laser emitting device LD described above to emit a laser beam onto the electrical conductor 92. During the process, the laser beam is steered to move the incident position according to a predetermined laser irradiation pattern. FIG. 7 shows the laser irradiation pattern used in the present embodiment. As described above, the laser beam is steered by the galvano scanner 833. The spot diameter Ds of the laser beam incident on the mount surface 92a of the electrical conductor 92 is about 2 to 20 μm, for example. The spot diameter Ds refers to the spot size (diameter) formed on the mount surface 92a of the electrical conductor 92 by the laser beam emitted from the laser emitting device LD.

The irradiation pattern shown in FIG. 7 is a grid pattern (see the bold arrows). The grid pattern includes a plurality of scan paths SO1 and a plurality of scan paths SO2. The scan paths SO1 extend in the orthogonal direction m1 and equally spaced apart in the orthogonal direction m2. The scan paths SO1 define straight lines that are parallel to each other. The scan paths SO2 extend in the orthogonal direction m2 and equally spaced apart in the orthogonal direction m1. The scan paths SO2 define straight lines that are parallel to each other. Note that the scan paths SO1 and SO2 shown in FIG. 7 indicate the paths for the center of the laser beam to follow. The scan paths SO1 and SO2 described above are one example and not of limitation.

In the roughening process, a laser beam is scanned first along the scan paths SO1 shown in FIG. 7. As a result, a plurality of first elongated trenches 951 are formed for the roughened area 95. In the example shown in FIG. 7, all the scan paths SO1 are scanned from one edge to the other edge in the same orthogonal direction m1. In another example, however, the scan paths SO1 may be scanned alternately in one orthogonal direction m1 and the reverse direction. The distance between the scan paths SO1, which means the pitch P_{SO1} of the scan paths SO1 (see FIG. 7), may be about 8 to 60 μm. Subsequently, a laser beam is scanned along the scan paths SO2 shown in FIG. 7. As a result, a plurality of second elongated trenches 952 are formed for the roughened area 95. In the example shown in FIG. 7, all the scan paths SO2 are scanned from one edge to the other edge in the same orthogonal direction m2. In another example, however, the scan paths SO2 may be scanned alternately in one orthogonal direction m2 and the reverse direction. The distance between the scan paths SO2, which means the pitch P_{SO2} of the scan paths SO2 (see FIG. 7), may be about 8 to 60 μm, which is the same as the pitch P_{SO1} of the scan paths SO1. In another example, however, the pitch P_{SO1} of the scan paths SO1 and the pitch P_{SO2} of the scan path SO2 may be different from each other. In addition, although the scan paths SO1 and the scan paths SO2 are substantially orthogonal as viewed in the first-axis direction z0, this is merely a non-limiting example.

As described above, the roughening process of this embodiment involves scanning a laser beam along the scan path SO1 and the scan paths SO2 to form the recesses 950, including the first elongated trenches 951 and the second elongated trenches 952. As a result, the roughened area 95 is formed on the mount surface 92a of the electrical conductor 92. Each region corresponding to where a scan path SO1 intersects a scan path SO2 is scanned twice, so that the trenches are deeper at such a region than at the regions corresponding to only one of the scan paths SO1 and S02. The size of the target area across which a laser beam is scanned (distance Lx0 and distance Ly0) may be changed as appropriate according to the roughened area 95 to be formed. In addition, the size of the roughened area 95 to be formed may be changed as appropriate according to the size of the semiconductor element 91 as viewed in the first-axis direction z0.

Next, a metal paste 930 for sintering is applied to the roughened area 95. The metal paste 930 is the base material for forming the sintered metal layer 93. For example, a silver paste may be used as the metal paste 930 for sintering. The silver paste may be composed of microscale or nanoscale silver particles dispersed in a solvent. In the present embodiment, the solvent of the silver paste for sintering contains no or substantially no epoxy resin. The process of applying the metal paste 930 for sintering (the paste application process) may be performed by screen printing in which the metal paste 930 is applied over a mask. Instead of screen printing, the metal paste 930 may be applied by using a dispenser. The application technique that can be used to apply the metal paste 930 is not limited to those mentioned above.

Next, the semiconductor element 91 is disposed on the metal paste 930 having been applied. In the process of placing the semiconductor element 91 (the mounting process), the semiconductor element 91 is oriented to face the element reverse surface 91b toward the mount surface 92a of the electrical conductor 92. With the element reverse surface 91b facing the mount surface 92a, the semiconductor element 91 is then placed onto the metal paste 930 for sintering. The semiconductor element 91 is placed to ensure that the entire semiconductor element 91 overlaps with the metal paste 930 having been applied, as viewed in the first-axis direction z0. As a result, the semiconductor element 91 is disposed on the metal paste 930 having been applied to the roughened area 95.

Subsequently, the metal paste 930 is sintered by thermal treatment to form a sintered metal layer 93. This process (the sintering process) involves thermal treatment of the metal paste 930 on which the semiconductor element 91 is placed, under predetermined sintering conditions, including pressure setting, heating duration, heating temperature, ambient environment (atmosphere) etc. In the present embodiment, the sintering conditions specify, but not limited to, that the heat treatment is performed at 200° C. for 2 hours in an oxygen atmosphere without applying pressure. Through the thermal treatment, the solvent is evaporated from the metal paste 930 and the silver particles of the metal paste 930 are fused together, forming a porous sintered metal layer 93.

Through the processes described above, the bonded structure A1 is formed that includes the electrical conductor 92 having the roughened area 95 on the surface (the mount surface 92a), the sintered metal layer 93 formed on the roughened area 95, and the semiconductor element 91 mounted on the electrical conductor 92 via the sintered metal layer 93. Note, however, that the forming processes described above are merely examples and not of limitation.

The following describes advantageous effects of the bonded structure A1 and the method of forming the same according to the first embodiment.

In the bonded structure A1, the electrical conductor 92 includes the roughened area 95 formed on the mount surface 92a by the roughening process. The sintered metal layer 93 is formed on and thus in contact with the roughened area 95. This configuration contributes to the anchoring effect of increasing the bonding strength between the sintered metal layer 93 and the electrical conductor 92. Consequently, the resistance to thermal stress is improved, reducing the risk of rupturing or peeling of the sintered metal layer 93. That is, the bonded structure A1 serves to improve thermal reliability.

In the bonded structure A1, the roughened area 95 is formed with the recesses 950 that are recessed in the first-axis direction z0 from the mount surface 92a. Specifically, the recesses 950 of the bonded structure A1 include the first elongated trenches 951 and the second elongated trenches 952 that intersect with each other. Due to these recesses 950, the roughened area 95 is rougher than the unroughened area of the mount surface 92a.

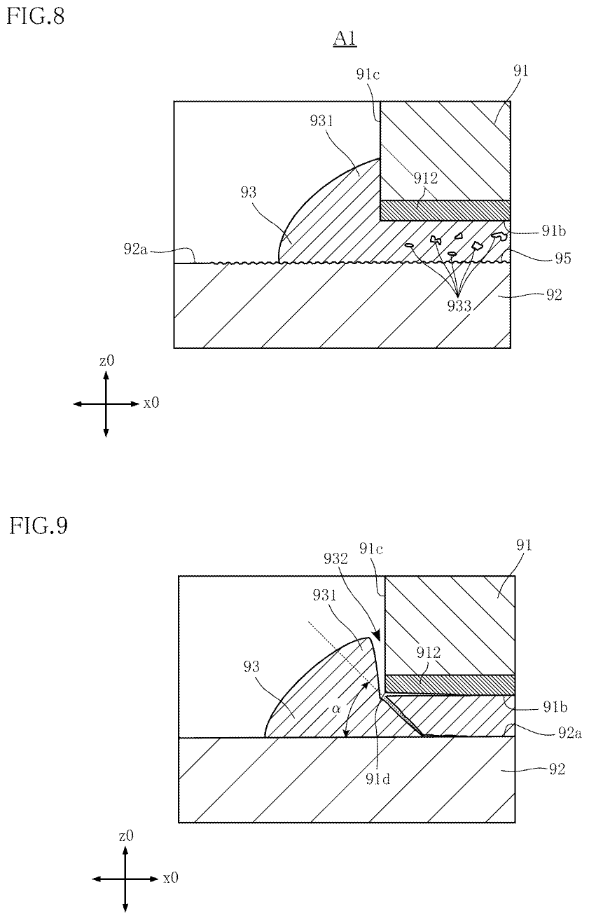

In the bonded structure A1, the recesses 950 of the roughened area 95 include the first elongated trenches 951 and the second elongated trenches 952. The present inventor conducted a heat cycle test on the bonded structure A1 to evaluate the effect caused by heat. FIG. 8 shows a schematic representation a section of the bonded structure A1 after the heat cycle test. For comparison, the same heat cycle test was conducted on a sample formed without a roughened area 95. FIG. 9 shows a schematic representation a section of the comparative sample (not having the roughened area 95) after the heat cycle test. For the heat cycle test, the minimum temperature was set to −40° C. and the maximum temperature was set to 150° C.

As shown in FIG. 9, a fracture 932 of the sintered metal layer 93 was observed in the comparative sample, which was formed without the roughened area 95. That is, the mount surface 92a of the electrical conductor 92 on which the sintered metal layer 93 was disposed was not roughened. The fracture 932 occurred at the interface between the element side surface 91c and the fillet 931, at a part of the interface between the mount surface 92a and the sintered metal layer 93 and at a part of the interface between the element reverse surface 91b of the semiconductor element 91 and the sintered metal layer 93. In addition, the fracture 932 extended across the sintered metal layer 93 in the first-axis direction z0, from the corner portion 91d between the element side surface 91c and the element reverse surface 91b to a point on the mount surface 92a under the semiconductor element 91. The fracture 932 extended obliquely from the corner portion 91d to the mount surface 92a of the electrical conductor 92 at an angle α relative to the mount surface 92a of the electrical conductor 92, for example. In contrast, no fracture like the fracture 932 was observed in FIG. 8, which shows the bonded structure A1 formed with the roughened area 95. That is, the sintered metal layer 93 was formed on the roughened area 95. Although minute void-like cracks 933 occurred at random, such minute cracks 933 may reduce conductivity and heat dispersion only to the extent less than that caused by peeling or rupturing of the sintered metal layer 93. As such, the bonded structure A1 serves to improve thermal reliability.

In the bonded structure A1, the first elongated trenches 951 intersect the second elongated trenches 952. That is, the recesses 950 are connected continuously across the roughened area 95. This configuration ensures that the metal paste 930 applied for sintering flows throughout the recesses by capillary-like action. The roughened area 95 is thus more wettable than the area not roughened. This allows the metal paste 930 applied for sintering to readily fill the recesses 950 (the first elongated trenches 951 and the second elongated trench 952). In the bonded structure A1, the line widths W₉₅₁ and W₉₅₂ of the first elongated trenches 951 and the second elongated trenches 952 are about 4 to 20 μm. The present inventor examined the capillary action of the metal paste 930 and confirmed that the rise of the liquid surface (capillary phenomenon) in a glass tube was more significant when the radius of the glass tube was about 10 μm or less. Note that the capillary phenomenon of water was confirmed to be more significant in a glass tube having a radius of about 30 μm or less. This demonstrates that the paste application process is effective to fill the recesses 950 with the metal paste 930 for sintering.

In the bonded structure A1, the dimension of the electrical conductor 92 in the first-axis direction z0 is about 0.4 to 3 mm. The present inventor has confirmed by his study that the risk of peeling or rupturing of the sintered metal layer 93 increases with an increase in the dimension in the first-axis direction z0 (i.e., the thickness) of the electrical conductor 92. However, heat dissipation by the electrical conductor 92 may be lowered if the electrical conductor 92 is too thin. In view of the above, the electrical conductor 92 measuring about 0.4 to 3 mm in the first-axis direction z0 is appropriate for reducing the risk of peeling or rupturing of the sintered metal layer 93 without lowering heat dispersion by the electrical conductor 92. As such, the bonded structure A1 is configured to further improve thermal reliability.

In the bonded structure A1, the dimension of the sintered metal layer 93 in the first-axis direction z0 is about 30 to 120 μm. The present inventor has confirmed by his study that the risk of peeling or rupturing of the sintered metal layer 93 increases with a decrease in the dimension in the first-axis direction z0 (i.e., the thickness) of the sintered metal layer 93. However, if the sintered metal layer 93 is too thick, the material cost for the sintered metal layer 93 may increase and the conductivity of the sintered metal layer 93 may decrease. In view of the above, the sintered metal layer 93 measuring about 30 to 120 μm in the first-axis direction z0 is appropriate for reducing the risk of peeling or rupturing of the sintered metal layer 93 without increasing the material cost and lowering the conductivity. That it, the bonded structure A1 is configured to be more thermally reliable and more industrially favorable.

According to the method of forming the bonded structure A1, the roughened area 95 is formed by scanning a laser beam in the roughening process. The laser beam is scanned along the linear scan paths SO1 and the linear scan paths SO2. As a result, the first elongated trenches 951 and the second elongated trenches 952 are formed in the roughened area 95. In addition, as a result of irradiation with a laser beam, fine asperities are formed on the surfaces of the first elongated trenches 951 and the second elongated trenches 952. That is, the roughening process of forming the roughened area 95 by laser irradiation works to form the first elongated trenches 951 and the second elongated trenches 952, and also to roughen the surfaces of the first elongated trenches 951 and the second elongated trenches 952. Thus, the anchoring effect is achieved by the asperities provided by the recesses 950 (the first elongated trenches 951 and the second elongated trenches 952), and also by the fine asperities formed on the surfaces of the first elongated trenches 951 and the second elongated trenches 952. That is, the bonded structure A1 is configured to further improve the bonding strength between the sintered metal layer 93 and the electrical conductor 92.

In the first embodiment, the roughened area 95 is formed by laser irradiation. In another embodiment, however, the roughened area 95 may be formed by blasting. The present inventor has found by his study that the roughened area 95 formed by blasting is more effective to increase the bonding strength between the sintered metal layer 93 and the electrical conductor 92 than the roughened area 95 formed by laser irradiation. In other words, forming the roughened area 95 by blasting serves to increase the bonding strength between the sintered metal layer 93 and the electrical conductor 92 and thus to improve thermal reliability. However, the study by the present inventor also shows that there is an imbalance between the bonding strength at the bonded interface between the sintered metal layer 93 and the electrical conductor 92 and the bonding strength between the sintered metal layer 93 and the semiconductor element 91, and that the imbalance is greater when the roughened area 95 is formed by blasting than when the roughened area 95 is formed by laser irradiation. In order to examine the effect caused by the imbalance, a heat cycle test was conducted on a sample having the roughened area 95 formed by blasting. As a result of the heat cycle test, peeling of the sintered metal layer 93 was observed at a part located outside of the semiconductor element 91 as viewed in the first-axis direction z0. Yet, no substantial rupturing or peeling, like the fracture 932 shown in FIG. 9, was observed at a part of the sintered metal layer 93 near the semiconductor element 91. This result indicates that forming the roughened area 95 by blasting is more effective than forming no roughened area to prevent lowering of the electrical conduction between the semiconductor element 91 and the electrical conductor 92 through the sintered metal layer 93. However, as shown in FIG. 8, the bonded structure A1 including the roughened area 95 formed by laser irradiation exhibited no substantial rupturing or peeling of the sintered metal layer 93, although some fine cracks 933 were observed. This is because the sintered metal layer 93 is provided with a more balanced bonding strength when the roughened area 95 formed by laser irradiation rather than by blasting, so that any thermal stress applied to the sintered metal layer 93 can be distributed throughout the sintered metal layer 93. That is, the bonded structure A1 is more thermally reliable than the bonding structure having the roughened area 95 formed by blasting. Note that the fine cracks 933 shown in FIG. 8 may occur as a result that thermal stress is distributed throughout the sintered metal layer 93.

In the first embodiment, the first elongated trenches 951 extend in the orthogonal direction m1 and the second elongated trenches 952 in the orthogonal direction m2. However, this is a non-limiting example. In another example, the first elongated trenches 951 may extend in the second-axis direction x0 and the second elongated trenches 952 in the third-axis direction y0. This example is still effective to increase the bonding strength between the sintered metal layer 93 and the electrical conductor 92 and thus to improve thermal reliability.

The first embodiment is described by way of example in which the first elongated trenches 951 and the second elongated trenches 952 extend in straight lines. In another example, however, the first elongated trenches 951 and the second elongated trenches 952 may extend in wavy or zigzag lines. In the present disclosure, zigzag lines are not limited to those having a series of turns at right angles and also include lines having turns at acute or obtuse angles. This example is still effective to increase the bonding strength between the sintered metal layer 93 and the electrical conductor 92 and thus improve thermal reliability.

Next, bonded structures according to other embodiments will be described. In the description below, elements that are the same as or similar to those of the first embodiments are denoted by the same reference signs, and a description of such an element will not be repeated.

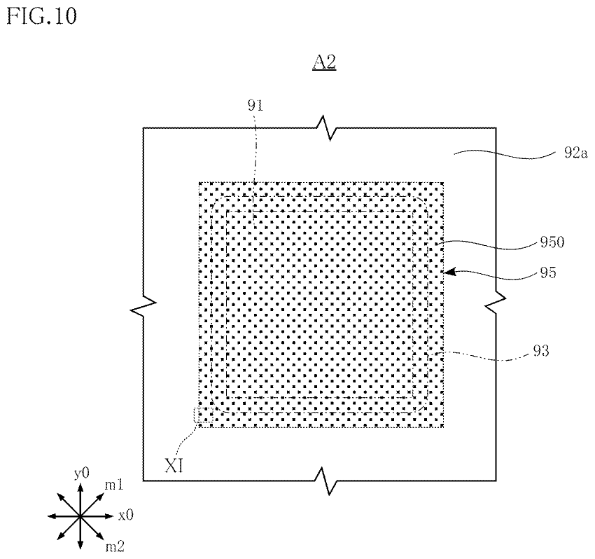

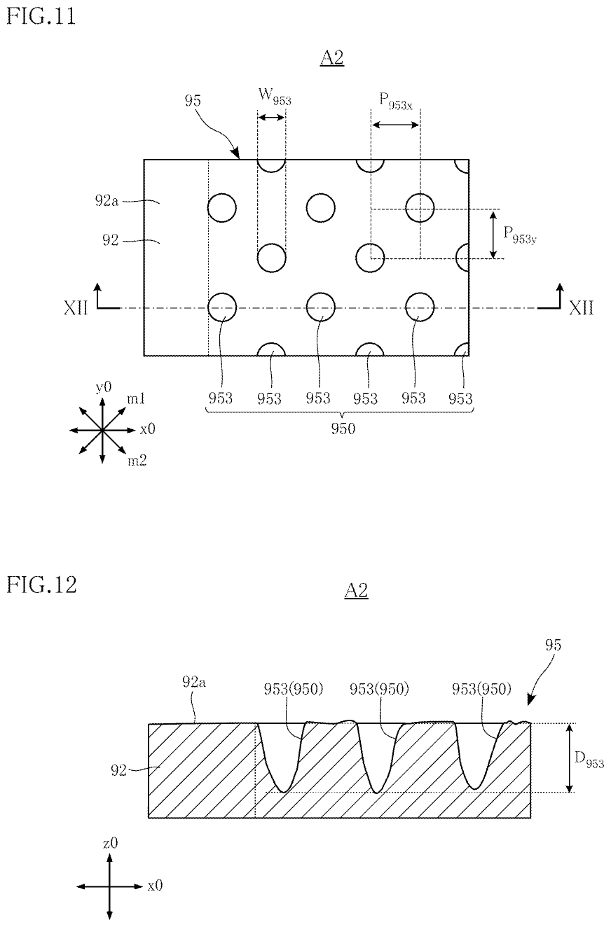

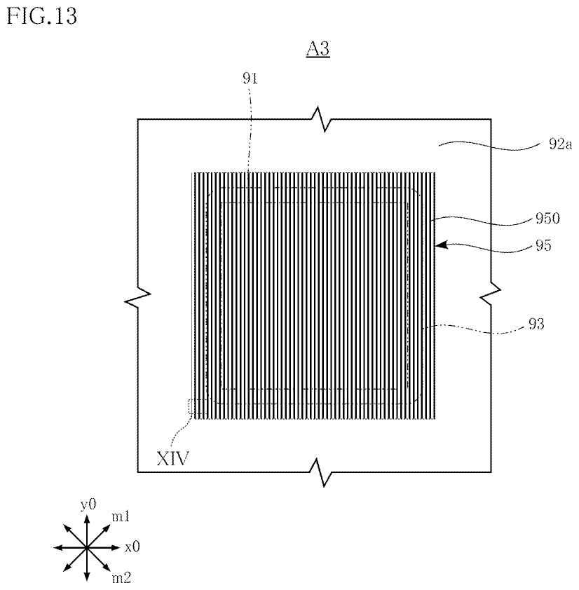

FIGS. 10 to 12 show a bonded structure according to a second embodiment. A bonded structure A2 according to the second embodiment differs in the configuration of the roughened area 95 from the bonded structure A1. FIG. 10 is a plan view of the bonded structure A2, showing the semiconductor element 91 and the sintered metal layer 93 in phantom (with two-dot chain line). FIG. 11 is an enlarged plan view showing area XI of FIG. 10. FIG. 12 is a sectional view taken along line XII-XII of FIG. 11.

As shown in FIG. 10, the roughened area 95 of this embodiment includes recesses 950 formed in a dot pattern as viewed in the first-axis direction z0. That is, the recesses 950 of this embodiment include a plurality of dimples 953.

Each dimple 953 may be conical, for example. As viewed in the first-axis direction z0, each dimple 953 is substantially circular, which may be substantially elliptical instead. The dimples 953 as viewed in the first-axis direction z0 may have a diameter W₉₅₃ (see FIG. 11) of about 20 μm, for example. Each dimple 953 is larger in cross section taken along a plane perpendicular to the first-axis direction z0, with approach toward the mount surface 92a in the first-axis direction z0. Each dimple 953 has a depth D₉₅₃ (see FIG. 12) of about 4 to 10 μm, for example. Of the plurality of dimples 953, each two closest dimples 953 (each two dimples 953 immediately adjacent in the orthogonal direction m1 or the orthogonal direction m2) are spaced apart from each other at a distance of P₉₅₃ₓ (see FIG. 11) of about 20 μm in the second-axis direction x0, and at a distance of P_{953y} (see FIG. 11) of about 20 μm in the third-axis direction y0. Note that the specific dimensions of the dimples 953 are not limited to the values mentioned above.

The dimples 953 may be formed by the roughening process by scanning a laser beam in a dot irradiation pattern. Specifically, a laser beam is emitted for a certain duration without moving, so that a certain spot is irradiated with the laser beam as in the first embodiment. As a result, the material at the irradiated spot of the electrical conductor 92 will sublime or melt. At this time, the depth of melting is deeper at the center of the laser beam as viewed in the first-axis direction z0.

The following describes advantageous effects of the bonded structure A2 according to the second embodiment.

In the bonded structure A2, the electrical conductor 92 includes the roughened area 95 formed on the mount surface 92a by the roughening process. The sintered metal layer 93 is formed on the roughened area 95. That is, the sintered metal layer 93 is formed on the rough surface of the electrical conductor 92. This configuration contributes to the anchoring effect of increasing the bonding strength between the sintered metal layer 93 and the electrical conductor 92. That is, the bonded structure A2 serves to improve thermal reliability in a manner similar to the bonded structure A1 of the first embodiment.

The roughened area 95 of the bonded structure A2 is formed with the recesses 950 that are recessed in the first-axis direction z0 from the mount surface 92a. Specifically, the recesses 950 of the bonded structure A2 include the dimples 953. Due to these recesses 950, the roughened area 95 is rougher than the unroughened area of the mount surface 92a.

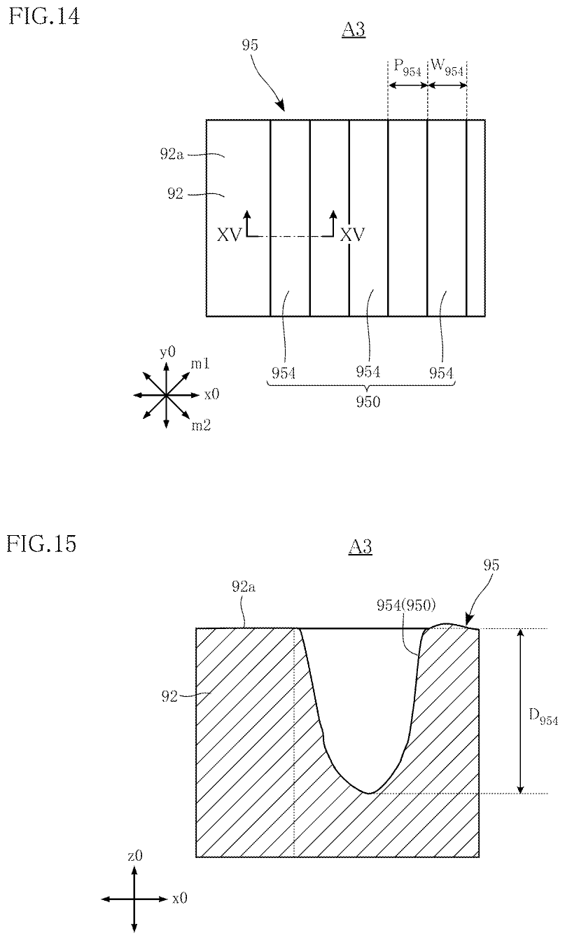

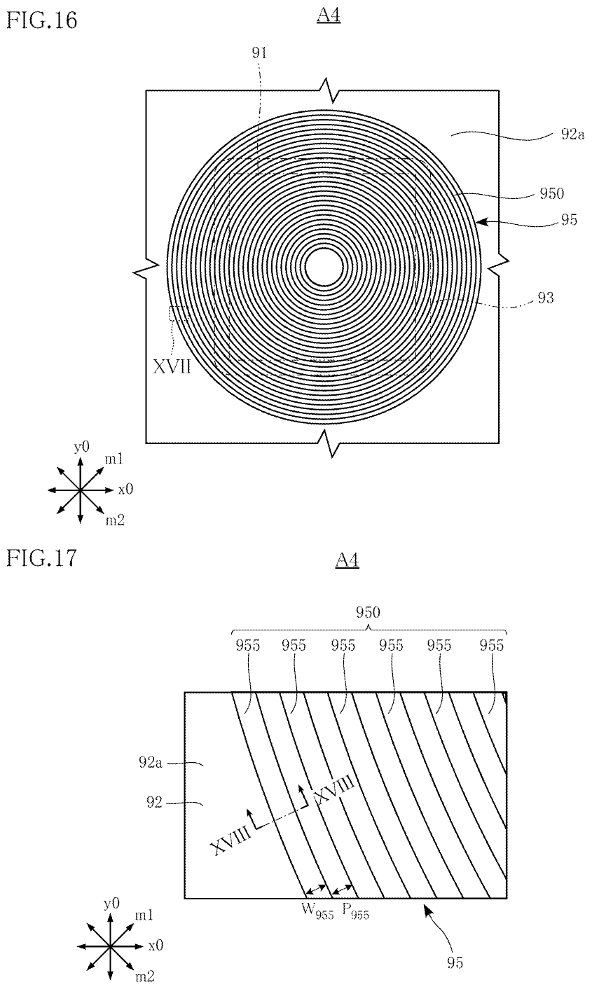

FIGS. 13 to 15 show a bonded structure according to a third embodiment. A bonded structure A3 according to the third embodiment differs in the configuration the roughened area 95 from the bonded structures A1 and A2. FIG. 13 is a plan view of the bonded structure A3, showing the semiconductor element 91 and the sintered metal layer 93 in phantom (with two-dot chain line). FIG. 14 is an enlarged plan view showing area XIV of FIG. 13. FIG. 15 is a sectional view taken along line XV-XV of FIG. 14.

As shown in FIG. 13, the roughened area 95 of this embodiment includes recesses 950 formed in a line pattern as viewed in the first-axis direction z0. That is, the recesses 950 of this embodiment include a plurality of elongated trenches 954. The elongated trenches 954 are formed by scanning a laser beam in a line pattern in the roughening process.

As viewed in the first-axis direction z0, the elongated trenches 954 extend in the direction y0. The elongated trenches 954 define substantially straight lines equally spaced apart in the direction x0. Each elongated trench 954 has a line width W₉₅₄ (see FIG. 14) of about 4 to 20 μm, for example. The distance P₉₅₄ (see FIG. 14) between each two adjacent elongated trenches 954 is about 4 to 40 μm, for example. Note that the line width W₉₅₄ may or may not be equal to the distance P₉₅₄. In addition, the depth D₉₅₄ of each elongated trench 954 is about 4 to 10 μm, for example. The specific dimensions of the elongated trenches 954 are not limited to the values mentioned above.

The following describes advantageous effects of the bonded structure A3 according to the third embodiment.

The bonded structure A3 includes the roughened area 95 formed on the mount surface 92a of the electrical conductor 92 by the roughening process. The sintered metal layer 93 is formed on the roughened area 95. That is, the sintered metal layer 93 is formed on the rough surface of the electrical conductor 92. This configuration contributes to the anchoring effect of increasing the bonding strength between the sintered metal layer 93 and the electrical conductor 92. Thus, the bonded structure A3 serves to improve thermal reliability in a manner similar to the bonded structure A1 of the first embodiment.

The roughened area 95 of the bonded structure A3 is formed with the recesses 950 that are recessed in the first-axis direction z0 from the mount surface 92a. Specifically, the recesses 950 of the bonded structure A3 include the elongated trenches 954 that are substantially parallel to each other. Due to these recesses 950, the roughened area 95 is rougher than the unroughened area of the mount surface 92a.

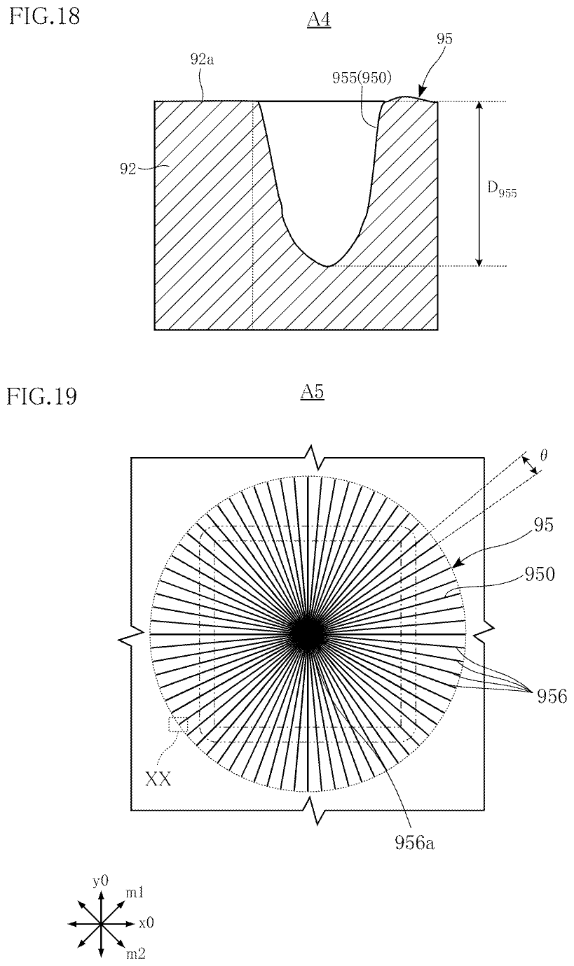

FIGS. 16 to 18 show a bonded structure according to a fourth embodiment. A bonded structure A4 according to the fourth embodiment differs in the configuration of the roughened area 95 from the bonded structures A1 to A3. FIG. 16 is a plan view of the bonded structure A4, showing the semiconductor element 91 and the sintered metal layer 93 in phantom (with two-dot chain line). FIG. 17 is an enlarged plan view showing area XVII of FIG. 16. FIG. 18 is a sectional view taken along line XVIII-XVIII of FIG. 17.

As shown in FIG. 16, the roughened area 95 of this embodiment includes recesses 950 formed in a pattern of concentric circles as viewed in the first-axis direction z0. That is, the recesses 950 of this embodiment include a plurality of ring-shaped grooves 955. The ring-shaped grooves 955 are formed by scanning a laser beam in a concentric circular pattern in the roughening process.

The ring-shaped grooves 955 are circular as viewed in the first-axis direction z0 and have substantially the same center as viewed in the first-axis direction z0. The ring-shaped grooves 955 define concentric circles. The innermost ring-shaped groove 955 has a diameter of about 1 μm, in plan view, and the outermost ring-shaped groove 955 contains the entire sintered metal layer 93 as viewed in the first-axis direction z0. Each ring-shaped groove 955 has a line width W₉₅₅ (see FIG. 17) of about 4 to 20 μm, for example. The distance P₉₅₅ (see FIG. 17) between each two adjacent ring-shaped grooves 955 is about 4 to 40 μm, for example. The line width W₉₅₅ and the distance P₉₅₅ may or may not be equal to each other. Each ring-shaped groove 955 has a depth D₉₅₅ (see FIG. 18) of about 4 to 10 μm, for example. The specific dimensions of the ring-shaped grooves 955 are not limited to the values mentioned above.

The following describes advantageous effects of the bonded structure A4 according to the fourth embodiment.

The bonded structure A4 includes the roughened area 95 formed on the mount surface 92a of the electrical conductor 92 by the roughening process. The sintered metal layer 93 is formed on the roughened area 95. That is, the sintered metal layer 93 is formed on the rough surface of the electrical conductor 92. This configuration contributes to the anchoring effect of increasing the bonding strength between the sintered metal layer 93 and the electrical conductor 92. Thus, the bonded structure A4 serves to improve thermal reliability in a manner similar to the bonded structure A1 of the first embodiment.

The roughened area 95 of the bonded structure A4 is formed with the recesses 950 that are recessed in the first-axis direction z0 from the mount surface 92a. Specifically, the recesses 950 of the bonded structure A4 include the concentric ring-shaped grooves 955. Due to these recesses 950, the roughened area 95 is rougher than the unroughened area of the mount surface 92a.

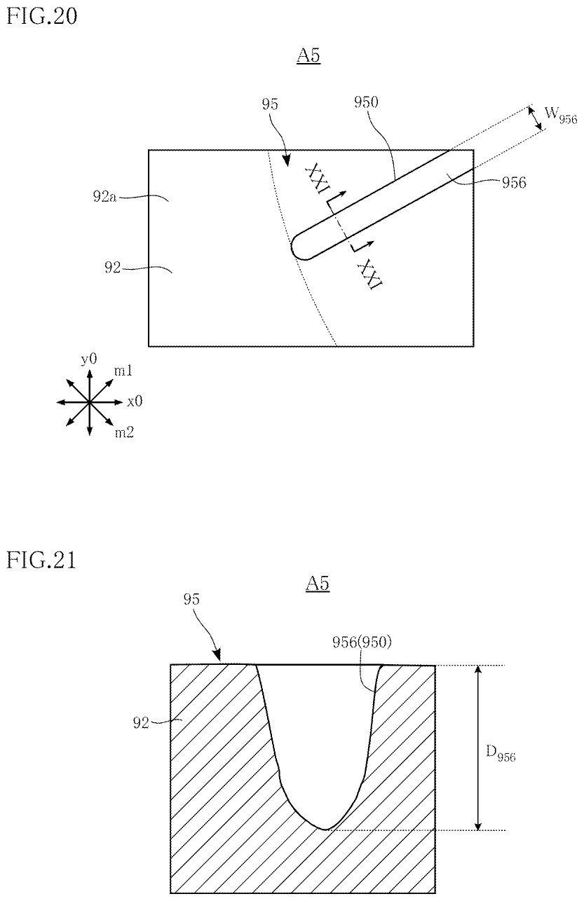

FIGS. 19 to 21 show a bonded structure according to a fifth embodiment. A bonded structure A5 according to the fifth embodiment differs in the configuration of the roughened area 95 from the bonded structures A1 to A4. FIG. 19 is a plan view of the bonded structure A5, showing the semiconductor element 91 and the sintered metal layer 93 in phantom (with two-dot chain line). FIG. 20 is an enlarged plan view showing area XX of FIG. 19. FIG. 21 is a sectional view taken along line XXI-XXI of FIG. 20.

As shown in FIG. 19, the roughened area 95 of this embodiment includes recesses 950 formed in a radial pattern as viewed in the first-axis direction z0. That is, the recesses 950 of this embodiment include a plurality of elongated trenches 956. The elongated trenches 956 are formed by scanning a laser beam in a radial pattern in the roughening process.

As viewed in the first-axis direction z0, the elongated trenches 956 extend radially from a reference position 956a as the center. In one example, the reference position 956a coincides with the center of the semiconductor element 91 as viewed in the first-axis direction z0. The angle θ (see FIG. 19) between each two radially adjacent elongated trenches 956 is about 5°, for example. Each elongated trench 956 has a line width W₉₅₆ (see FIG. 20) of about 4 to 20 μm, for example. Each elongated trench 956 has a depth D₉₅₆ of about 4 to 10 μm, for example. The specific dimensions of the elongated trenches 956 are not limited to the values mentioned above.

The following describes advantageous effects of the bonded structure A5 according to the fifth embodiment.

The bonded structure A5 includes the roughened area 95 formed on the mount surface 92a of the electrical conductor 92 by the roughening process. The sintered metal layer 93 is formed on the roughened area 95. That is, the sintered metal layer 93 is formed on the roughened surface of the electrical conductor 92. This configuration contributes to the anchoring effect of increasing the bonding strength between the sintered metal layer 93 and the electrical conductor 92. Thus, the bonded structure A5 serves to improve thermal reliability in a manner similar to the bonded structure A1 of the first embodiment.

The roughened area 95 of the bonded structure A5 is formed with the recesses 950 that are recessed in the first-axis direction z0 from the mount surface 92a. Specifically, the recesses 950 of the bonded structure A5 include the elongated trenches 956 that extend radially. Due to these recesses 950, the roughened area 95 is rougher than the unroughened area of the mount surface 92a.

Note that the elongated trenches 956 of the fifth embodiment all start from and thus connected at the reference position 956a, which however is a non-limiting example. In another example, the reference position 956a may be left unprocessed by a laser beam, so that a region around the reference position 956a may be left as an unprocessed (not roughened) region.

The first to fifth embodiments are directed to examples in which the sintered metal layer 93 is in direct contact with the roughened area 95, which however is not of limitation. For example, the roughened area 95 is coated with silver plating before forming, and then the sintered metal layer 93 is formed on the silver plating. Also, the electrical conductor 92 may be coated with silver plating before the roughened area 95 is formed. The silver plating may have a thickness of about 3 μm, for example. In this variation, the thickness (the dimension in the first-axis direction z0) of the electrical conductor 92 mentioned above is the finished dimension of a part in contact with the sintered metal layer 93 and thus includes the plating thickness. In the example in which silver plating coats the entire electrical conductor 92 rather than only the roughened area 95, the dimensions of the electrical conductor 92 in the first-axis direction z0, the second-axis direction x0 and the third-axis direction y0 all refer to the finished dimensions and thus include the thickness of the silver plating.

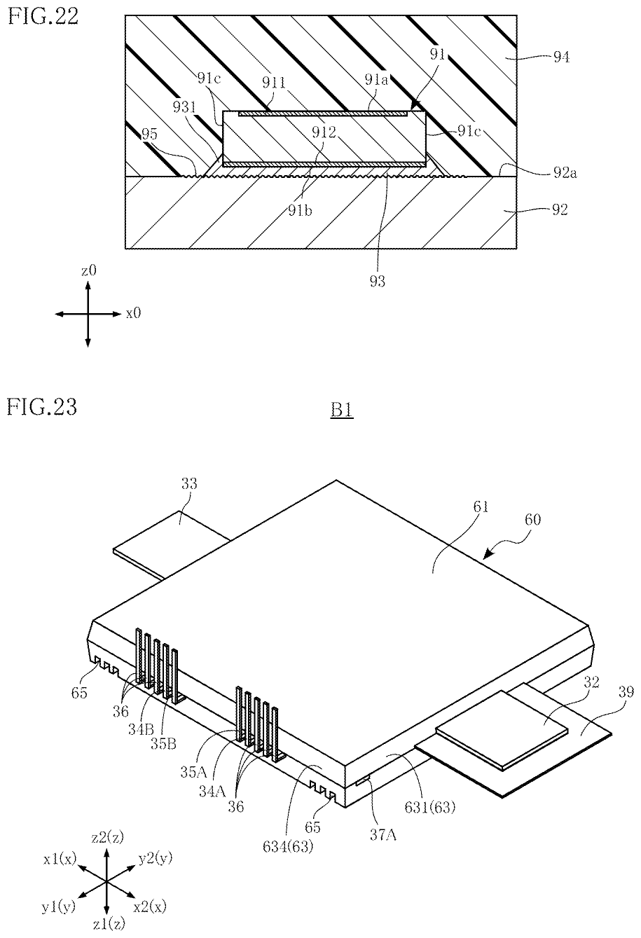

In the first to fifth embodiments, the semiconductor element 91 is exposed to ambient air, which however is a non-limiting example. For example, the semiconductor element 91 may be covered with a resin member 94 made of an epoxy resin, as shown in FIG. 22. In such an example, the resin member 94 is formed on the mount surface 92a of the electrical conductor 92 and covers the semiconductor element 91 and the sintered metal layer 93. This encapsulating resin member 94 restricts the thermal expansion of the semiconductor element 91 and electrical conductor 92. As a result, the sintered metal layer 93 will receive a greater thermal stress, which increases the risk of rupturing or peeling of the sintered metal layer 93. In view of the risk, the thermal reliability can be improved effectively by forming the roughened area 95 and disposing the sintered metal layer 93 on the roughened area 95 to increase the bonding strength between the sintered metal layer 93 and the electrical conductor 92.

Next, a semiconductor device according to the present disclosure will be described with reference to FIGS. 23 to 34. A semiconductor device B1 of the present disclosure includes an insulating substrate 10, a plurality of conductive members 11, a plurality of switching elements 20, a plurality of conductive bonding layers 29, two input terminals 31 and 32, an output terminal 33, a pair of gate terminals 34A and 34B, a pair of sensing terminals 35A and 35B, a plurality of dummy terminals 36, a pair of side terminals 37A and 37B, a pair of insulating layers 41A and 41B, a pair of gate layers 42A and 42B, a pair of sensing layers 43A and 43B, a plurality of base portions 44, a plurality of cord-like connecting members 51, a plurality of plate-like connecting members 52 and a sealing resin 60. The plurality of switching elements 20 include a plurality of switching elements 20A and a plurality of switching elements 20B. The conductive members 11 of the semiconductor device B1 include the roughened areas 95 described above and thus include the bonded structures A1 described above.

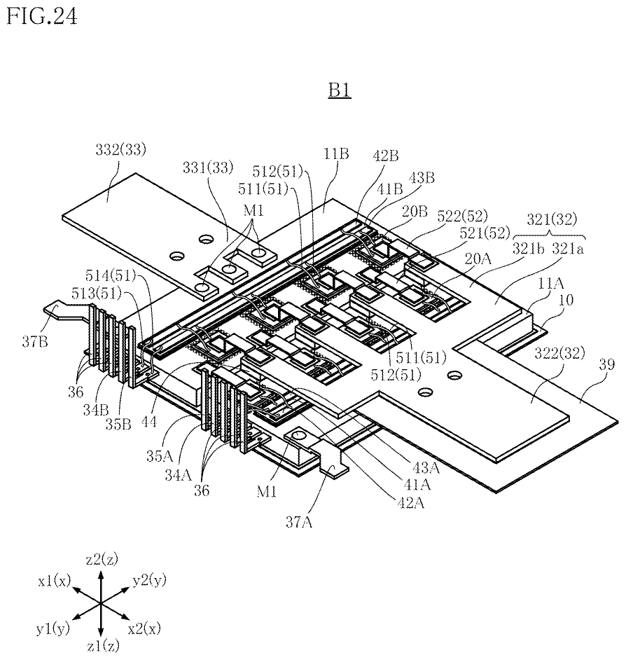

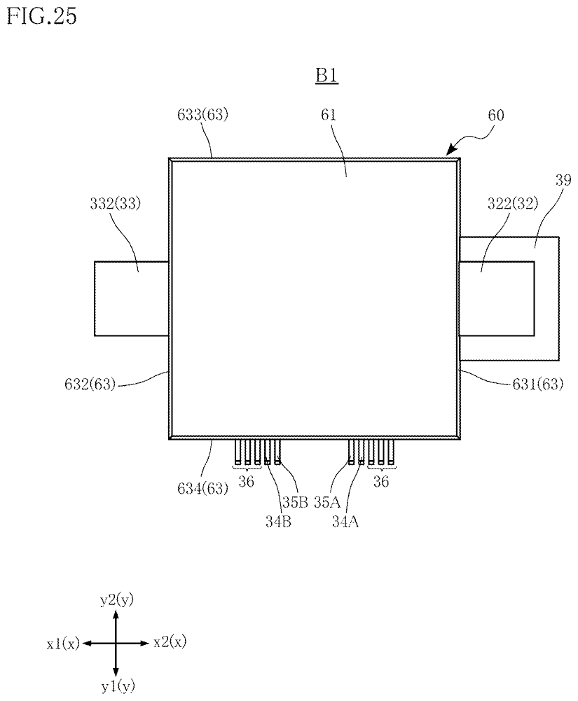

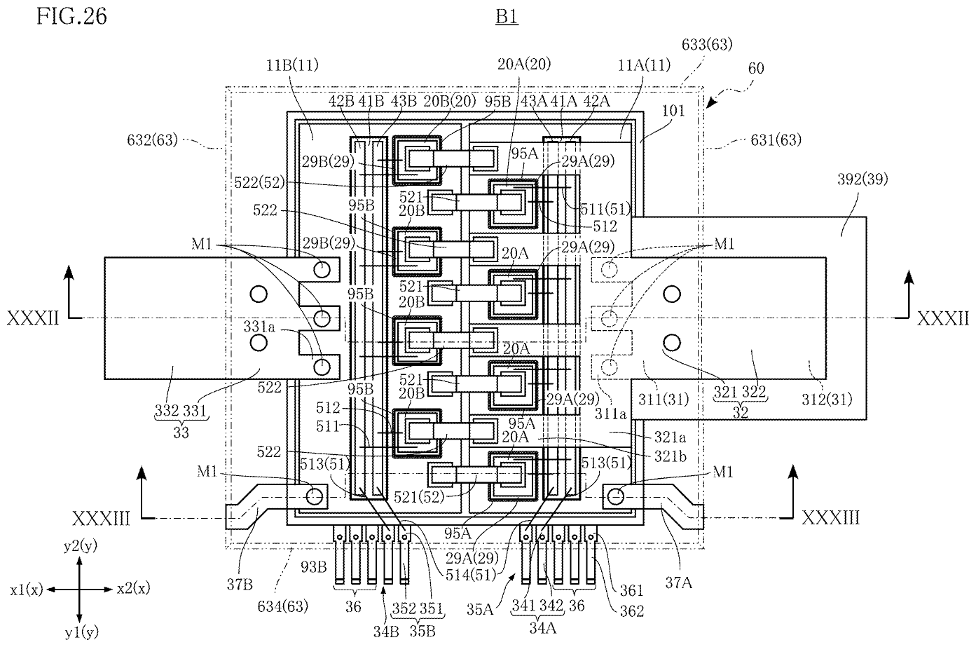

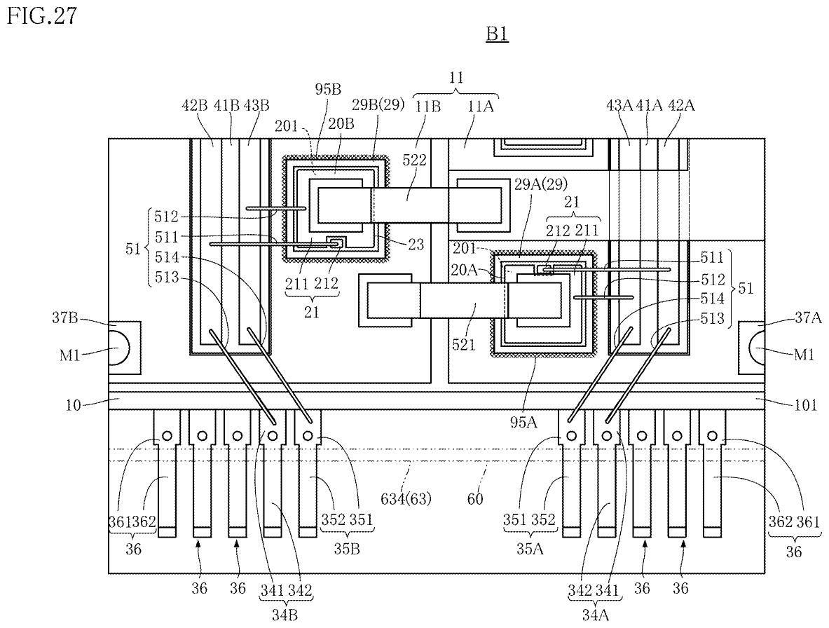

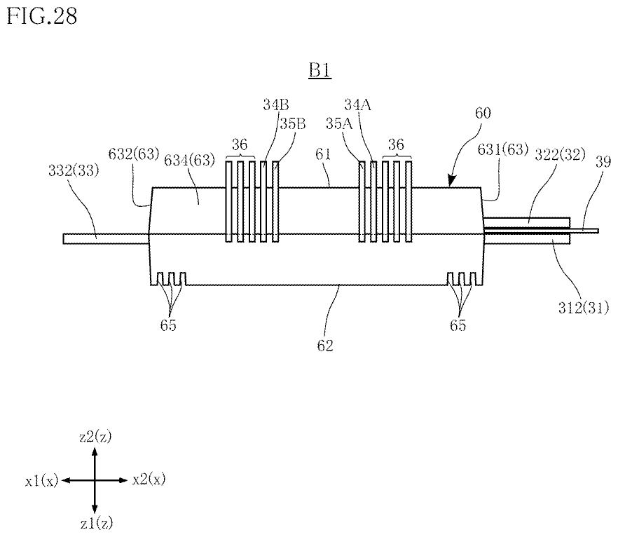

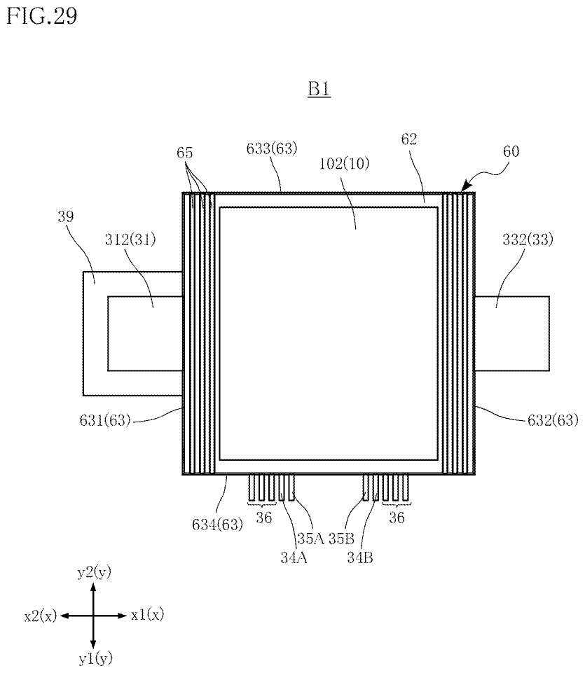

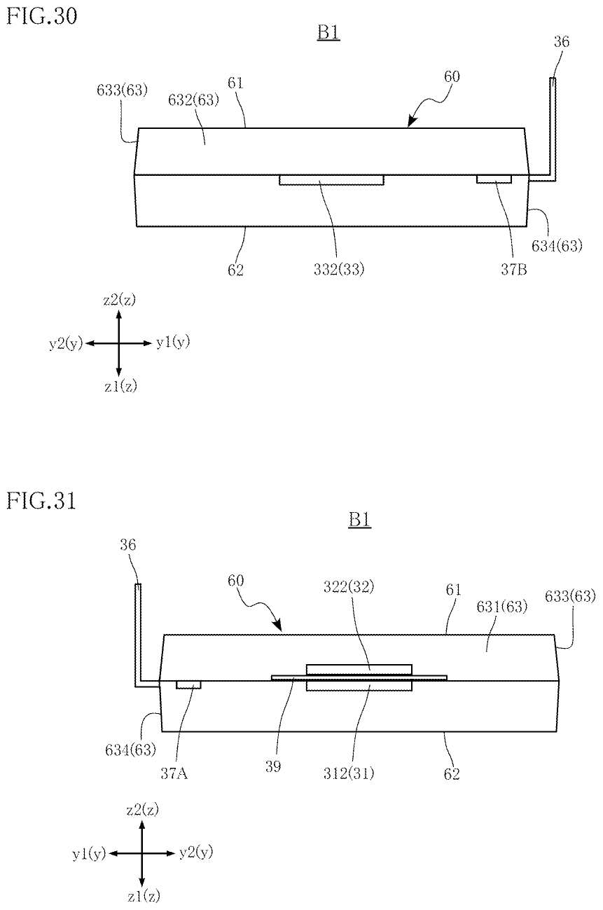

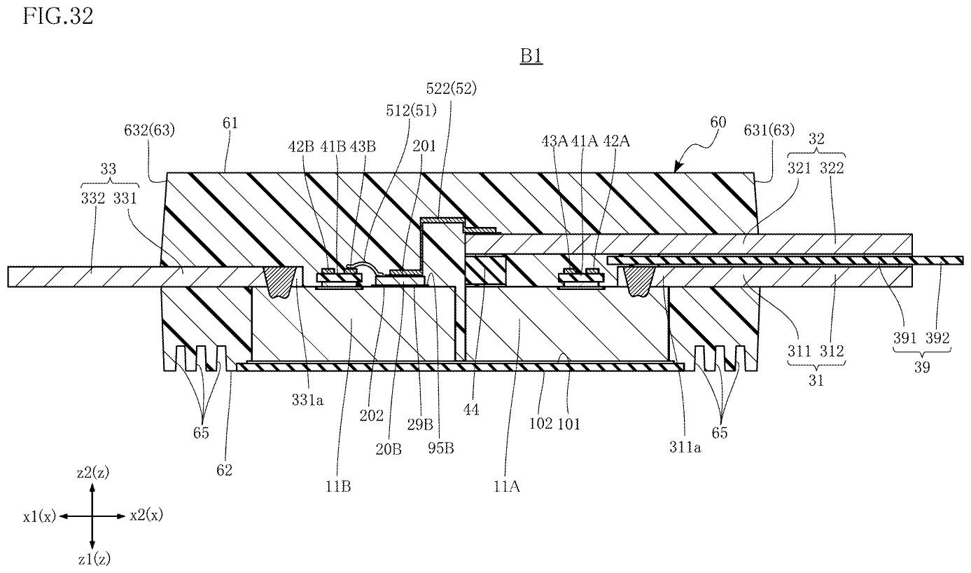

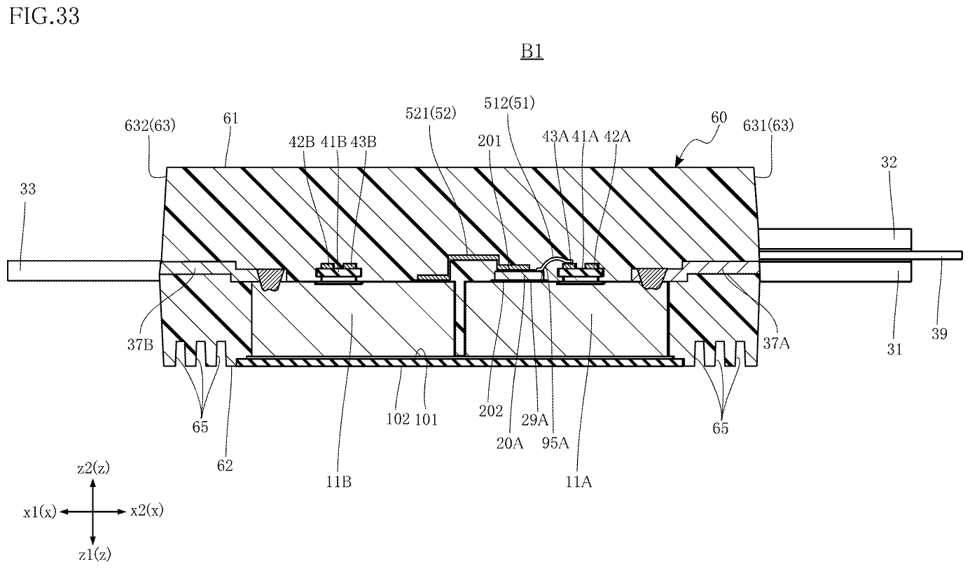

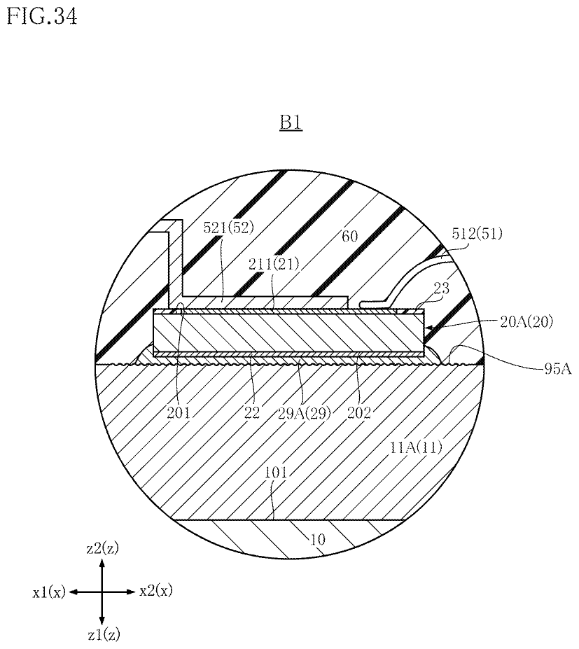

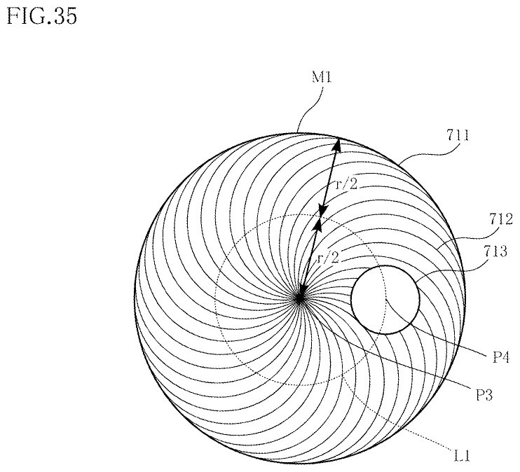

FIG. 23 is a perspective view of the semiconductor device B1. FIG. 24 is a perspective view similar to FIG. 23, but omitting the sealing resin 60. FIG. 25 is a plan view of the semiconductor device B1. FIG. 26 is a plan view similar to FIG. 25, but showing the sealing resin 60 in phantom (in two-dot chain line). FIG. 27 is an enlarged plan view showing a part of FIG. 26. FIG. 28 is a front view of the semiconductor device B1. FIG. 29 is a bottom view of the semiconductor device B1. FIG. 30 is a side view (left-side view) of the semiconductor device B1. FIG. 31 is a side view (right-side view) of the semiconductor device B1. FIG. 32 is a sectional view taken along line XXXII-XXXII of FIG. 26. FIG. 33 is a sectional view taken along line XXXIII-XXXIII of FIG. 26. FIG. 34 is an enlarged view showing an essential part of FIG. 33, showing the sectional structure of a switching element 20.

For convenience, FIGS. 23 to 34 define three directions perpendicular to each other as a width direction x, a depth direction y and a thickness direction z. The thickness direction z corresponds to the first-axis direction z0 of the bonded structure A1. The width direction x corresponds to the horizontal direction as seen in the plan view of the semiconductor device B1 (see FIGS. 25 and 26). The width direction x corresponds to the second-axis direction x0 of the bonded structure A1. The depth direction y corresponds to the vertical direction as seen in the plan view of the semiconductor device B1 (see FIGS. 25 and 26). The depth direction y corresponds to the third-axis direction y0 of the bonded structure A1. Where necessary, one side in the width direction x is specifically referred to as a width direction x1, and the other side as a width direction x2. Similarly, one side in the depth direction y is specifically referred to as a depth direction y1, and the other side as a depth direction y2. Also, one side in the thickness direction z is specifically referred to as a thickness direction z1, and the other side as a thickness direction z2.

As shown in FIGS. 24, 26, 32 and 33, the conductive members 11 are disposed on the insulating substrate 10. The insulating substrate 10 serves as a base supporting the conductive members 11 and the switching elements 20. The insulating substrate 10 is electrically insulative. The insulating substrate 10 may be made of a ceramic material having a high thermal conductivity, for example. One example of such a ceramic material is AlN (aluminum nitride). In the present embodiment, the insulating substrate 10 is rectangular as viewed in the thickness direction z (hereinafter also “plan view”). As shown in FIGS. 32 and 33, the insulating substrate 10 has an obverse surface 101 and a reverse surface 102.

The obverse surface 101 and the reverse surface 102 are spaced apart and face away from each other in the thickness direction z. The obverse surface 101 faces in the thickness direction z2, which is the side in the thickness direction z at which the conductive members 11 are arranged. The obverse surface 101 is covered with the sealing resin 60, together with the conductive members 11 and the switching elements 20. The reverse surface 102 faces in the thickness direction z1. As shown in FIGS. 29, 32 and 33, the reverse surface 102 is exposed from the sealing resin 60. The reverse surface 102 may be connected to a heat sink (not shown), for example. The insulating substrate 10 is not limited to the configuration described above. For example, a plurality of separate insulating substrates 10 may be provided for the respective conductive members 11.

The conductive members 11 are metal plates. The metal plates is made of Cu or a Cu alloy, for example. The conductive members 11 constitute a conductive path to the switching elements 20 via the two input terminals 31 and 32 and the output terminal 33. The conductive members 11 are spaced apart from each other on the obverse surface 101 of the insulating substrate 10. The conductive members 11 are bonded to the obverse surface 101 via a bonding material such as silver (Ag) paste. The dimension of the conductive members 11 in the thickness direction z may be, but not limited to, about 3.0 mm, for example. The conductive members 11 may be coated with Ag plating. In this case, the dimension of the conductive members 11 in the thickness direction z mentioned above refers to the finished dimension, which includes the thickness of the silver plating. Each conductive member 11 corresponds to the electrical conductor 92 of the bonded structure

A1.

The conductive members 11 include two conductive members 11A and 11B. As shown in FIGS. 24 and 26, the conductive member 11A is located at the side of the conductive member 11B in the width direction x2. The switching elements 20A are mounted on the conductive member 11A. The switching elements 20B are mounted on the conductive member 11B. The conductive members 11A and 11B are rectangular in plan view. Each of the conductive members 11A and 11B may be formed with a groove on the surface facing in the thickness direction z2. For example, the conductive member 11A may have one or more grooves. In plan view, the grooves extend in the depth direction y between the plurality of switching elements 20A and the insulating layer 41A (described later). Similarly, the conductive member 11B may have one or more grooves. In plan view, the grooves extend in the depth direction y between the plurality of switching elements 20B and the insulating layer 41B (described later).

As shown in FIGS. 24, 26 and 27, the conductive members 11A and 11B have the roughened areas 95A and 95B on parts of their surfaces (facing in the thickness direction z2). The roughened areas 95A and 95B have the same configuration as the roughened area 95 in the bonded structure A1 described above. Alternatively, however, the roughened areas 95A and 95B may have the same configuration as any of the roughened areas 95 in the bonded structures A2 to A5. The roughened areas 95A are formed for the respective switching elements 20A to be mounted. As viewed in the thickness direction z, the roughened areas 95A overlap with the respective switching elements 20A. Similarly, the roughened areas 95B formed for the respective switching elements 20B to be mounted. As viewed in the thickness direction z, the roughened areas 95B overlap with the respective switching elements 20B. Note, however, that the roughened areas 95A and 95B to be formed are not limited to the example described above. For example, the roughened area may be formed on the entire upper surface of each of the conductive members 11A and 11B, or one continuous roughened area 95A (or 95B) may be formed for mounting all of the switching elements 20A (or 20B) thereon.

The configuration of the conductive members 11 is not limited to the example described above, and may be modified as appropriate according to the performance required for the semiconductor device B1. For example, the shape, size, arrangement, etc., of each conductive member 11 may be changed based on the number, arrangement, etc., of the switching elements 20.

Each switching element 20 corresponds to the semiconductor element 91 of the bonded structure A1 described above. In the present embodiment, the switching elements 20 are metal-oxide-semiconductor field-effect transistors (MOSFETs) formed from a semiconductor material, which mainly is silicon carbide (SiC). However, the switching elements 20 are not limited to MOSFETs, and may be field effect transistors including metal-insulator-semiconductor FETs (MISFETs), bipolar transistors such as insulated gate bipolar transistors (IGBTs), and IC chips such as LSIs.

In the present embodiment, all of the switching elements 20 are the same n-channel MOSFETs. The switching elements 20 may be, but not limited to, rectangular in plan view.

Each switching element 20 has an element obverse surface 201 and an element reverse surface 202 as shown in FIG. 34, which shows one switching element 20A. The element obverse surface 201 and the element reverse surface 202 are spaced apart and face away from each other in the thickness direction z. The element obverse surface 201 faces in the same direction as the obverse surface 101 of the insulating substrate 10. The element reverse surface 202 faces the obverse surface 101 of the insulating substrate 10.

As shown in FIG. 34, each switching element 20 has an obverse-surface electrode 21, a reverse-surface electrode 22 and an insulating film 23.

The obverse-surface electrode 21 is provided on the element obverse surface 201. The obverse-surface electrode 21 corresponds to the obverse-surface electrode 911 of the bonded structure A1 described above. As shown in FIG. 27, the obverse-surface electrode 21 includes a first electrode 211 and a second electrode 212. The first electrode 211 may be a source electrode through which a source current flows. In addition, the second electrode 212 may be a gate electrode to which a gate voltage is applied for driving the switching element 20. The first electrode 211 is larger than the second electrode 212. Although the first electrode 211 shown in FIG. 27 has one continuous area, it may have of a plurality of separate areas.

The reverse-surface electrode 22 is provided on the element reverse surface 202. The reverse-surface electrode 22 corresponds to the reverse-surface electrode 912 of the bonded structure A1 described above. The reverse-surface electrode 22 is formed on the entire element reverse surface 202. The reverse-surface electrode 22 may be a drain electrode through which a drain current flows.

The insulating film 23 is provided on the element obverse surface 201. The insulating film 23 is electrically insulative. The insulating film 23 surrounds the obverse-surface electrode 21 in plan view. For example, the insulating film 23 is formed by stacking a silicon dioxide (SiO₂) layer, a silicon nitride (SiN₄) layer, and a polybenzoxazole layer in the stated order on the element obverse surface 201. Note that the insulating film 23 may include a polyimide layer instead of the polybenzoxazole layer.

As described above, the switching elements 20 include the switching elements 20A and the switching elements 20B. As shown FIGS. 24 and 26, four switching elements 20A and four switching elements 20B are included in the semiconductor device B1. The number of the switching elements 20 is not limited to this example, and may be changed as appropriate according to the performance required for the semiconductor device B1. For example, when the semiconductor device B1 is a half-bridge switching circuit, the semiconductor device B1 may include a plurality of switching elements 20A constituting an upper arm circuit and a plurality of switching elements 20B constituting a lower arm circuit.

As shown in FIG. 26, the switching elements 20A are disposed on the conductive member 11A. The switching elements 20A are spaced apart from each other in a row in the depth direction y. As shown in FIG. 34, each switching element 20A is electrically bonded to the conductive member 11A via a conductive bonding layer 29. The element reverse surface 202 of the switching element 20A faces the upper surface (the surface facing in the thickness direction z2) of the conductive member 11A. The reverse-surface electrode 22 of the switching element 20A is electrically connected to the conductive member 11A via the conductive bonding layer 29.

As shown in FIG. 26, the switching elements 20B are disposed on the conductive member 11B. The switching elements 20B are spaced apart from each other in a row in the depth direction y. Each switching element 20B is electrically bonded to the conductive member 11B via a conductive bonding layer 29. The element reverse surface 202 of the switching element 20B faces the upper surface (the surface facing in the thickness direction z2) of the conductive member 11B. The reverse-surface electrode 22 of the switching element 20B is electrically connected to the conductive member 11B via the conductive bonding layer 29.

The conductive bonding layers 29 electrically bond the respective switching elements 20 to the corresponding conductive members 11. The conductive bonding layers 29 have the same configuration as the sintered metal layer 93 of the bonded structure A1 described above. Thus, the conductive bonding layers 29 are made of sintered metal (e.g., sintered silver). The conductive bonding layers 29 include a plurality of first bonding layers 29A and a plurality of second bonding layers 29B.

Each first bonding layer 29A is disposed between, and electrically bond a switching element 20A and the conductive member 11A. That is, the switching element 20A is bonded to the conductive member 11A via the first bonding layer 29A. The first bonding layers 29A are disposed on the respective roughened areas 95A formed on the upper surface (the surface facing in the thickness direction z2) of the conductive member 11A.

Each second bonding layer 29B is disposed between, and electrically bond a switching element 20B and the conductive member 11B. That is, the switching element 20B is bonded to the conductive member 11B via the second bonding layer 29B. The second bonding layers 29B are disposed on the respective roughened areas 95B formed on the upper surface (the surface facing in the thickness direction z2) of the conductive member 11B.

Each of the two input terminals 31 and 32 is a metal plate. The metal plates are made of Cu or a Cu alloy, for example. The dimension of the input terminals 31 and 32 in the thickness direction z may be, but not limited to, about 0.8 mm, for example. As shown in FIGS. 28 and 32, each of the two input terminals 31 and 32 is arranged at a position offset in the width direction x2 in the semiconductor device B1. A source voltage, for example, is applied between the two input terminals 31 and 32. The source voltage may be applied between the input terminals 31 and 32 directly from a power source (not shown) or via a busbar (not shown) disposed to sandwich and thus connected to the input terminals 31 and 32. In addition, a snubber circuit may be connected in parallel. The input terminal 31 acts as a positive electrode (P terminal), and the input terminal 32 acts as a negative electrode (N terminal). In the thickness direction z, the input terminal 32 is spaced apart from the input terminal 31 and also from the conductive member 11A.

As shown in FIGS. 26 and 32, the input terminal 31 has a pad portion 311 and a terminal portion 312.

The pad portion 311 is a part of the input terminal 31 covered with the sealing resin 60. The end of the pad portion 311 in the width direction x1 has a comb-like shape, and includes a plurality of prongs 311a. The prongs 311a are electrically bonded to the surface of the conductive member 11A. The bonding may be done by laser welding with a laser beam, by ultrasonic welding, or by using a conductive bonding material. In this embodiment, the prongs 311a are bonded to the conductive member 11A by laser welding and have weld marks M1 (see FIG. 35), which are visible in plan view.

FIG. 35 shows an example of a weld mark M1. The weld mark M1 is not limited to the example shown in FIG. 35 and may have any shape or features formed as a result of laser welding. The weld mark M1 shown in FIG. 35 has a circumferential edge 711, a plurality of streaks 712 and a crater 713.

The circumferential edge 711 is the boundary of the weld mark M1. In plan view, the circumferential edge 711 defines a ring shape having the center on a reference point P3. Although the circumferential edge 711 shown in FIG. 35 is perfectly circular, some distortions and irregularities may be caused at the time of laser welding.

As shown in FIG. 35, each streak 712 has the shape of an arc in plan view. Specifically, each streak 712 in plan view extends outward from the reference point P3, which is at the center of the circumferential edge 711, to the circumferential edge 711, drawing a curve projecting in the same annular direction along the circumferential edge 711. In the present embodiment, the circumferential edge 711 is circular in plan view, so that the annular directions refer to the circumferential directions of the circle. In the example shown in FIG. 35, the curve of each streak 712 projects in a counterclockwise direction circumferentially of the circumferential edge 711.

The crater 713 is circular in plan view. The crater 713 has a smaller radius than the circumferential edge 711 in plan view. The center P4 of the crater 713 in plan view falls on a midpoint of a line segment connecting the center of the circumferential edge 711 (corresponding to the reference point P3) to the circumferential edge 711. FIG. 35 shows an auxiliary line L1 depicted by connecting the midpoints of such line segments.

The terminal portion 312 is a part of the input terminal 31 exposed from the sealing resin 60. As shown in FIGS. 26 and 32, the terminal portion 312 extends from the sealing resin 60 in the width direction x2 in plan view.

As shown in FIGS. 26 and 33, the input terminal 32 has a pad portion 321 and a terminal portion 322.

The pad portion 321 is a part of the input terminal 32 covered with the sealing resin 60. The pad portion 321 includes a connecting portion 321a and a plurality of extended portions 321b. The connecting portion 321a has a band shape extending in the depth direction y. The connecting portion 321a is connected to the terminal portion 322. Each extended portion 321b has a band shape extending from the connecting portion 321a in the width direction x1. The extended portions 321b are spaced apart from each other in the depth direction y in plan view. Each extended portion 321b is in contact with a corresponding one of the base portions 44 at the surface facing in the thickness direction z1 and is supported on the conductive member 11A via the base portion 44.

The terminal portion 322 is a part of the input terminal 32 exposed from the sealing resin 60. As shown in FIGS. 26 and 32, the terminal portion 322 extends from the sealing resin 60 in the width direction x2 in plan view. The terminal portion 322 is rectangular in plan view. As shown in FIGS. 26 and 32, the terminal portion 322 overlaps with the terminal portion 312 of the input terminal 31 in plan view. The terminal portion 322 is spaced apart from the terminal portion 312 in the thickness direction z2. The terminal portion 322 may have the same shape as the shape of terminal portion 312.

The output terminal 33 is a metal plate. The metal plate is made of Cu or a Cu alloy, for example. As shown in FIG. 28, the output terminal 33 is arranged at a position offset in the width direction x1 in the semiconductor device B1. The output terminal 33 outputs AC power (voltage) converted by the switching elements 20.

As shown in FIGS. 26 and 32, the output terminal 33 has a pad portion 331 and a terminal portion 332.

The pad portion 331 is a part of the output terminal 33 covered with the sealing resin 60. The end of the pad portion 331 in the width direction x2 has a comb-like shape, and includes a plurality of prongs 331a. The prongs 331a are electrically bonded to the surface of the conductive member 11B. The bonding may be done by laser welding with a laser beam, by ultrasonic welding, or by using a conductive bonding material. In this embodiment, the prongs 331a are bonded to the conductive member 11B by laser welding and have weld marks M1 (see FIG. 35), which are visible in plan view.

The terminal portion 332 is a part of the output terminal 33 exposed from the sealing resin 60. As shown in FIGS. 26 and 32, the terminal portion 332 extends from the sealing resin 60 in the width direction x1 in plan view.

As shown in FIGS. 25 to 27 and 29, the gate terminals 34A and 34B are respectively adjacent to the conductive members 11A and 11B in the depth direction y. The gate terminal 34A is used to apply a gate voltage for driving the switching elements 20A. The gate terminal 34B is used to apply a gate voltage for driving the switching elements 20B.

As shown in FIGS. 26 and 27, each of the gate terminals 34A and 34B has a pad portion 341 and a terminal portion 342. The pad portions 341 of the gate terminals 34A and 34B are covered with the sealing resin 60. As such, the gate terminals 34A and 34B are supported by the sealing resin 60. The pad portions 341 may be coated with Ag plating, for example. The terminal portions 342 are connected to the respective pad portions 341 and exposed from the sealing resin 60. Each terminal portion 342 has an L-shape as viewed in the width direction x.

As shown in FIGS. 26 to 28, the sensing terminals 35A and 35B are respectively adjacent to the gate terminals 34A and 34B in the width direction x. The sensing terminal 35A detects voltage applied to the obverse-surface electrode 21 (the first electrode 211) of each switching element 20A (i.e., voltage corresponding to the source current). The sensing terminal 35B detects voltage applied to the obverse-surface electrode 21 (the first electrode 211) of each switching element 20B (i.e., voltage corresponding to the source current).

As shown in FIGS. 26 and 27, each of the sensing terminals 35A and 35B has a pad portion 351 and a terminal portion 352. The pad portions 351 of the sensing terminals 35A and 35B are covered with the sealing resin 60. As such, the sensing terminals 35A and 35B are supported by the sealing resin 60. The pad portions 351 may be coated with silver plating, for example. The terminal portions 352 are connected to the respective pad portions 351 and exposed from the sealing resin 60. Each terminal portion 352 has an L-shape as viewed in the width direction x.

As shown in FIGS. 25 to 27 and 29, each dummy terminal 36 is located at the side of the gate terminal 34A or 35B opposite from the corresponding one of the sensing terminals 35A and 35B in the width direction x. In the present embodiment, six dummy terminals 36 are provided. Three of the six dummy terminals 36 are located at one side in the width direction x (the side in the width direction x2), and the other three dummy terminals 36 at the other side in the width direction x (the side in the width direction x1). The number of the dummy terminals 36 is not limited to six as in the example above. In an alternative example, the dummy terminals 36 may be omitted.

As shown in FIGS. 26 and 27, each of the dummy terminal 36 has a pad portion 361 and a terminal portion 362. The pad portions 361 of the dummy terminals 36 are covered with the sealing resin 60. As such, the dummy terminals 36 are supported by the sealing resin 60. The pad portions 361 may be coated with silver plating, for example. The terminal portions 362 are connected to the respective pad portions 361 and exposed from the sealing resin 60. Each terminal portion 362 has an L-shape as viewed in the width direction x. In the example shown in FIGS. 23 to 31, the terminal portions 362 have the same shape as the terminal portions 342 of the gate terminals 34A and 34B and the terminal portions 352 of the sensing terminals 35A and 35B.

As shown in FIGS. 25, 26 and 33, in plan view, each of the side terminals 37A and 37B is disposed in a region where the edge of the sealing resin 60 in the depth direction y1 meets one edge of the sealing resin 60 in the width direction x. The side terminal 37A is bonded to the conductive member 11A and covered with the sealing resin 60 except at the end face facing in the width direction x2. The side terminal 37B is bonded to the conductive member 11B and covered with the sealing resin 60 except at the end face facing in the width direction x1. In plan view, the entire side terminals 37A and 37B may overlap with the sealing resin 60. The side terminals 37A and 37B may be bonded by laser welding with a laser beam, by ultrasonic welding, or by using a conductive bonding material. In the present embodiment, the side terminals 37A and 37B are bonded respectively to the conductive members 11A and 11B by laser welding. As a result, each side terminal has a weld mark M1 (see FIG. 35), which is visible in plan view. Each of the side terminals 37A and 37B has a bent in plan view and another bent in the thickness direction z. The configurations of the side terminals 37A and 37B are not limited to the example described above. For example, each of the side terminals 37A and 37B may have a part extending out of the resin side surface 631 or 632 in plan view. Also, the semiconductor device B1 may be without the side terminals 37A and 37B.

As shown in FIGS. 25 to 27, the gate terminals 34A and 34B, the sensing terminals 35A and 35B and the dummy terminals 36 are arranged in a row in the width direction x in plan view. For the semiconductor device B1, the gate terminals 34A and 34B, the sensing terminals 35A and 35B, the dummy terminals 36, and the side terminals 37A and 37B are all formed from the same lead frame.

The insulating member 39 is electrically insulative and is made of an insulating sheet, for example. As shown in FIG. 33, a part of the insulating member 39 is a flat plate disposed between the terminal portion 312 of the input terminal 31 and the terminal portion 322 of the input terminal 32 in the thickness direction z. In plan view, the entire input terminal 31 overlaps with the insulating member 39. As for the input terminal 32, a part of the pad portion 321 and the entire terminal portion 322 overlap with the insulating member 39 in plan view. The insulating member 39 insulates the two input terminals 31 and 32 from each other. The insulating member 39 has a part (which is offset in the width direction x1) covered with the sealing resin 60.

As shown in FIG. 32, the insulating member 39 has an intervening portion 391 and an extended portion 392. The intervening portion 391 is interposed between the terminal portion 312 of the input terminal 31 and the terminal portion 322 of the input terminal 32 in the thickness direction z. The entire intervening portion 391 is disposed between the terminal portion 312 and the terminal portion 322. The extended portion 392 extends in the width direction x2 from the intervening portion 391 beyond the terminal portion 312 and the terminal portion 322.

The insulating layers 41A and 41B are electrically insulative, and made of a glass epoxy resin, for example. As shown in FIG. 26, each of the insulating layers 41A and 41B has a band shape elongated in the depth direction y. As shown in FIGS. 26, 27, 32 and 33, the insulating layer 41A is bonded to the upper surface (the surface facing in the thickness direction z2) of the conductive member 11A. The insulating layer 41A is offset further in the width direction x2 than the switching elements 20A. As shown in FIGS. 26, 27, 32 and 33, the insulating layer 41B is bonded to the upper surface (the surface facing in the thickness direction z2) of the conductive member 11B. The insulating layer 41B is offset further in the width direction x1 than the switching elements 20B.

The gate layers 42A and 42B are electrically conductive and are made of Cu, for example. As shown in FIG. 26, each of the gate layers 42A and 42B has a band shape elongated in the depth direction y. As shown in FIGS. 26, 27, 32 and 33, the gate layer 42A is disposed on the insulating layer 41A. The gate layer 42A is electrically connected to the second electrodes 212 (the gate electrodes) of the respective switching elements 20A via the cord-like connecting members 51 (specifically, gate wires 511 described later). As shown in FIGS. 26, 27, 32 and 33, the gate layer 42B is disposed on the insulating layer 41B. The gate layer 42B is electrically connected to the second electrodes 212 (the gate electrodes) of the respective switching elements 20B via the cord-like connecting members 51 (specifically, gate wires 511 described later).

The sensing layers 43A and 43B are electrically conductive and are made of Cu, for example. As shown in FIG. 26, each of the sensing layers 43A and 43B has a band shape elongated in the depth direction y. As shown in FIGS. 26, 27, 32 and 33, the sensing layer 43A is disposed on the insulating layer 41A, along with the gate layer 42A. On the insulating layer 41A, the sensing layer 43A is adjacent to the gate layer 42A and spaced apart from the gate layer 42A. In this example, the sensing layer 43A is located closer to the switching elements 20A than the gate layer 42A. That is, the sensing layer 43A is located at the side of the gate layer 42A in the width direction x1. The sensing layer 43A is electrically connected to the first electrodes 211 (the source electrodes) of the respective switching elements 20A via the cord-like connecting members 51 (specifically, sensing wires 512 described later). As shown in FIGS. 26, 27, 32 and 33, the sensing layer 43B is disposed on the insulating layer 41B, along with the gate layer 42B. On the insulating layer 41B, the sensing layer 43B is adjacent to the gate layer 42B and spaced apart from the gate layer 42B. In this example, the sensing layer 43B is located closer to the switching elements 20B in the width direction x than the gate layer 42B. That is, the sensing layer 43B is located at the side of the gate layer 42B in the width direction x2. The sensing layer 43B is electrically connected to the first electrodes 211 (the source electrodes) of the respective switching elements 20B via the cord-like connecting members 51 (specifically, sensing wires 512 described later).

The base portions 44 are electrically insulative and are made of a ceramic material, for example. As shown in FIGS. 24 and 32, the base portions 44 are bonded to the surface of the conductive member 11A. Each base portion 44 is rectangular in plan view, for example. The base portions 44 are spaced apart from each other in a row in the depth direction y. The dimension of each base portion 44 in the thickness direction z is substantially equal to the total dimension of the input terminal 31 and the insulating member 39 in the thickness direction z. The base portions 44 are bonded to the respective extended portions 321b of the pad portion 321 of the input terminal 32. The base portions 44 support the input terminal 32.

The cord-like connecting members 51 are common bonding wires. The cord-like connecting members 51 are electrically conductive and are made of aluminum (A1), gold (Au) or Cu, for example. As shown in FIGS. 26 and 27, the cord-like connecting members 51 include a plurality of gate wires 511, a plurality of sensing wires 512, a pair of first connecting wires 513 and a pair of second connecting wires 514.

As shown in FIGS. 26 and 27, each gate wire 511 is bonded at one end to the second electrode 212 (the gate electrode) of the corresponding switching element 20, and the other end to the corresponding gate layer 42A or 42B. The gate wires 511 include those electrically connecting the second electrodes 212 of the switching elements 20A to the gate layer 42A, and those electrically connecting the second electrodes 212 of the switching elements 20B to the gate layer 42B.

As shown in FIGS. 26 and 27, each sensing wire 512 is bonded at one end to the first electrode 211 (the source electrode) of the corresponding switching element 20, and the other end to the corresponding sensing layer 43A or 43B. The sensing wires 512 include those electrically connecting the first electrodes 211 of the switching elements 20A to the sensing layer 43A, and those electrically connecting the first electrodes 211 of the switching elements 20B to the sensing layer 43B.

As shown in FIGS. 26 and 27, one of the first connecting wires 513 connects the gate layer 42A and the gate terminal 34A, and the other connects the gate layer 42B and the gate terminal 34B. More specifically, one of the first connecting wires 513 is bonded at one end to the gate layer 42A and the other end to the pad portion 341 of the gate terminal 34A, thereby electrically connecting the gate layer 42A and the gate terminal 34A. The other first connecting wire 513 is bonded at one end to the gate layer 42B and at the other end to the pad portion 341 of the gate terminal 34B, thereby electrically connection the gate layer 42B and the gate terminal 34B.

As shown in FIGS. 26 and 27, one of the second connecting wires 514 connects the sensing layer 43A and the sensing terminal 35A, and the other connects the sensing layer 43B and the sensing terminal 35B. More specifically, one of the second connecting wires 514 is bonded at one end to the sensing layer 43A and the other end to the pad portion 351 of the sensing terminal 35A, thereby electrically connecting the sensing layer 43A and the sensing terminal 35A. The other second connecting wire 514 is bonded at one end to the sensing layer 43B and the other end to the pad portion 351 of the sensing terminal 35B, thereby electrically connecting the sensing layer 43B and the sensing terminal 35B.

The plate-like connecting members 52 are electrically conductive and are made of A1, Au or Cu, for example. The plate-like connecting members 52 may be formed by bending a metal plate. As shown in FIGS. 24, 25 and 27, the plate-like connecting members 52 include a plurality of first leads 521 and a plurality of second leads 522. The semiconductor device B1 may include bonding wires similar to the cord-like connecting members 51, instead of the plate-like connecting members 52.

As shown in FIGS. 24, 26 and 27, the first leads 521 connect the respective switching elements 20A to the conductive member 11B. Each first lead 521 is bonded at one end to the first electrode 211 (the source electrode) of the corresponding switching element 20A, and the other end to the surface of the conductive member 11B.

As shown in FIGS. 24, 26 and 27, the second leads 522 connect the respective switching elements 20B to the input terminal 32. Each second lead 522 is bonded at one end to the first electrode 211 (the source electrode) of the corresponding switching element 20B, and the other end to one of the extended portions 321b of the pad portion 321 of the input terminal 32. The second leads 522 may be bonded with a silver paste or solder, for example. In this embodiment, each second lead 522 is bent in the thickness direction z.

As shown in FIGS. 27 and 28, the sealing resin 60 covers the insulating substrate 10 (except the reverse surface 102), the conductive members 11, the switching elements 20, the cord-like connecting members 51 and the plate-like connecting members 52. The sealing resin 60 is made of an epoxy resin, for example. As shown in FIGS. 23, 25, 26 and 28 to 31, the sealing resin 60 has a resin obverse surface 61, a resin reverse surface 62 and a plurality of resin side surfaces 63.

The resin obverse surface 61 and the resin reverse surface 62 are spaced apart and face away from each other in the thickness direction z. The resin obverse surface 61 faces in the thickness direction z2, and the resin reverse surface 62 faces in the thickness direction z1. In the bottom view shown in FIG. 29, the resin reverse surface 62 has the shape of a frame surrounding the reverse surface 102 of the insulating substrate 10. Each resin side surface 63 is disposed between the resin obverse surface 61 and the resin reverse surface 62 and connected to both the surfaces 61 and 62. The resin side surfaces 63 include a pair of resin side surfaces 631 and 632 spaced apart in the width direction x, and a pair of resin side surfaces 633 and 634 spaced apart in the depth direction y. The resin side surface 631 faces in the width direction x2, and the resin side surface 632 faces in the width direction x1. The resin side surface 633 faces in the depth direction y2, and the resin side surface 634 faces in the depth direction y1.

As shown in FIGS. 23, 28 and 29, the sealing resin 60 includes a plurality of recesses 65 each of which is recessed from the resin reverse surface 62 in the thickness direction z and extends in the depth direction y. In plan view, each recess 65 is continuous across the resin reverse surface 62, from one edge in the depth direction y1 to the other edge in the depth direction y2. The recesses 65 are formed such that, in plan view, the reverse surface 102 of the insulating substrate 10 are flanked by three recesses 65 on the respective sides in the width direction x. Alternatively, the recesses 65 of the sealing resin 60 may be omitted.

Next, advantageous effects of the semiconductor device B1 according to the present disclosure will be described.

The semiconductor device B1 includes the switching elements 20A electrically bonded to the conductive member 11A via the respective first bonding layers 29A. The conductive member 11A includes the roughened areas 95A formed on the surface. Each first bonding layer 29A is formed on a roughened areas 95A. That is, the semiconductor device B1 includes the bonded structures A1 each of which is formed by a switching element 20A as the semiconductor element 91, the conductive member 11A as the electrical conductor 92, and a first bonding layer 29A as the sintered metal layer 93. The first bonding layer 29A serves to improve the bonding strength between the switching element 20A and the conductive member 11A. Consequently, the first bonding layer 29A is less prone to rupturing or peeling by heat, which enables the semiconductor device B1 to prevent lowering of the electric conductivity and heat dispersion.

The semiconductor device B1 includes the switching elements 20B electrically bonded to the conductive member 11B via the respective second bonding layers 29B. The conductive member 11B includes the roughened areas 95B formed on the surface. Each second bonding layer 29B is formed on a roughened area 95B. That is, the semiconductor device B1 includes the bonded structures A1 each of which is formed by a switching element 20B as the semiconductor element 91, the conductive member 11B as the electrical conductor 92, and a second bonding layer 29B as the sintered metal layer 93. The second bonding layer 29B serves to improve the bonding strength between the switching element 20B and the conductive member 11B. Consequently, the second bonding layer 29B is less prone to rupturing or peeling by heat, which enables the semiconductor device B1 to prevent lowering of the electric conductivity and heat dispersion.

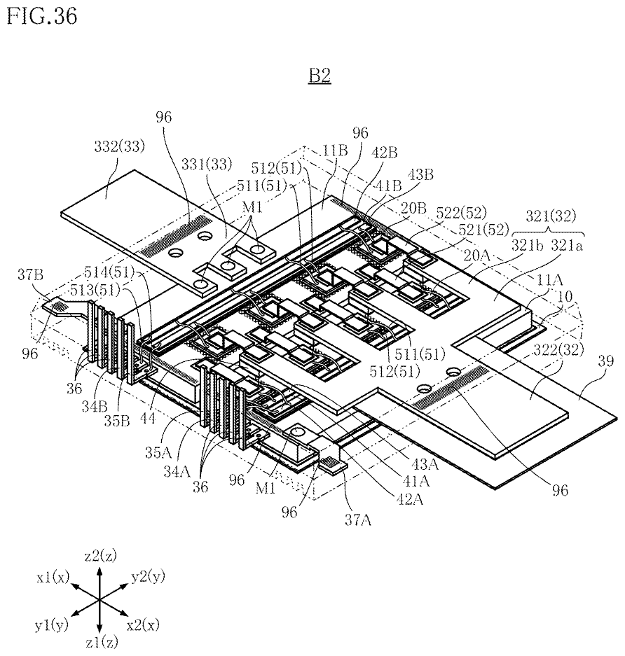

Next, semiconductor devices according to other embodiments will be described with reference to FIGS. 36 to 38.

FIG. 36 shows a semiconductor device B2. Different from the semiconductor device B1, the semiconductor device B2 includes additional roughened areas formed by laser irradiation, other than the roughened areas on which the switching elements 20 are mounted. Specifically, roughened areas 96, which are different from the roughened areas 95, are formed on the conductive members 11A and 11B, the input terminal 32, the output terminal 33 and the side terminals 37A and 37B. FIG. 36 is a perspective view of the semiconductor device B2, showing the sealing resin 60 in phantom (with two-dot chain line).

As shown in FIG. 36, the roughened areas 96 are formed on parts of the conductive members 11A and 11B, the input terminal 32, the output terminal 33 and the side terminals 37A and 37B. In plan view, each roughened areas 96 is formed on a part overlapping with the circumferential edge of the sealing resin 60 on a corresponding one of the conductive members 11A and 11B, the input terminal 32, the output terminal 33 and the side terminals 37A and 37B.

Like the roughened areas 95, the roughened areas 96 are formed by laser irradiation. Each roughened area 96 is formed by scanning a laser beam in a line pattern. As a result, the recesses 950 of the roughened area 96 include a plurality of elongated trenches 954 that are parallel to each other in a manner similar to the roughened area 95 shown in FIG. 13. The irradiation pattern of a laser beam is not limited to a line pattern, and may be a grid pattern, a concentric circular pattern, a radial pattern or a dot pattern. With the grid irradiation pattern, the resulting roughened area 96 will be similar to the roughened area 95 shown in FIGS. 1 and 3. With the concentric circular irradiation pattern, the resulting roughened area 96 will be similar to the roughened area 95 shown in FIG. 16. With the radial irradiation pattern, the resulting roughened area 96 will be similar to the roughened area 95 shown in FIG. 19. With the dot irradiation pattern, the resulting roughened area 96 will be similar to the roughened area 95 shown in FIG. 10. The semiconductor device B2 includes the roughened areas 95 and the roughened areas 96, and their configurations may be the same or different from each other.

The semiconductor device B2 including the bonded structures A1 is less prone to rupturing or peeling of the conductive bonding layers 29, and thus has a higher bonding strength between the switching elements 20 and the conductive members 11. The semiconductor device B2 is therefore enabled to prevent the lowering of electric conductivity and heat dispersion.

The roughened areas 96 of the semiconductor device B2 are formed on parts of the conductive members 11A and 11B, the input terminal 32, the output terminal 33 and the side terminals 37A and 37B. The sealing resin 60 is in contact with the roughened areas 96. This configuration contributes to the anchoring effect so that the sealing resin 60 is bonded more firmly to the conductive members 11A and 11B, the input terminal 32, the output terminal 33 and the side terminals 37A and 37B. In this way, the roughened areas 96 have the effect of increasing the bonding strength between the respective components and the sealing resin 60. That is, the semiconductor device B2 is configured such that the bonding strength of the sealing resin 60 is increased by the roughened areas 95 and the bonding strength of the conductive bonding layers 29 is increased by the roughened areas 96. That is, the semiconductor device B1 is less prone to rupturing or peeling of the conductive bonding layers 29 and also to rupturing or peeling of the sealing resin 60.

The semiconductor device B2 may be modified by changing the width of the trenches in the roughened areas 95 (the width of the first elongated trenches 951 and the second elongated trenches 952) and the width of the trenches in roughened areas 96 (the width of the elongated trenches 954). In a manner similar to the examination of the metal paste 930, the present inventor examined the capillary action of the epoxy resin and confirmed that the rise of the liquid surface (capillary phenomenon) in a glass tube was more significant when the radius of the glass tube was about 20 μm or less. That is, the trenches in the roughened area 96 may be made wider than the trenches in the roughened area 95, without substantial impact on the wettability of the roughened areas to the epoxy resin. That is, the width of the trenches in the roughened area 96 may be increased to reduce the time and labor required for laser irradiation. The semiconductor devices B2 according to this modification can therefore improve manufacturing yields.

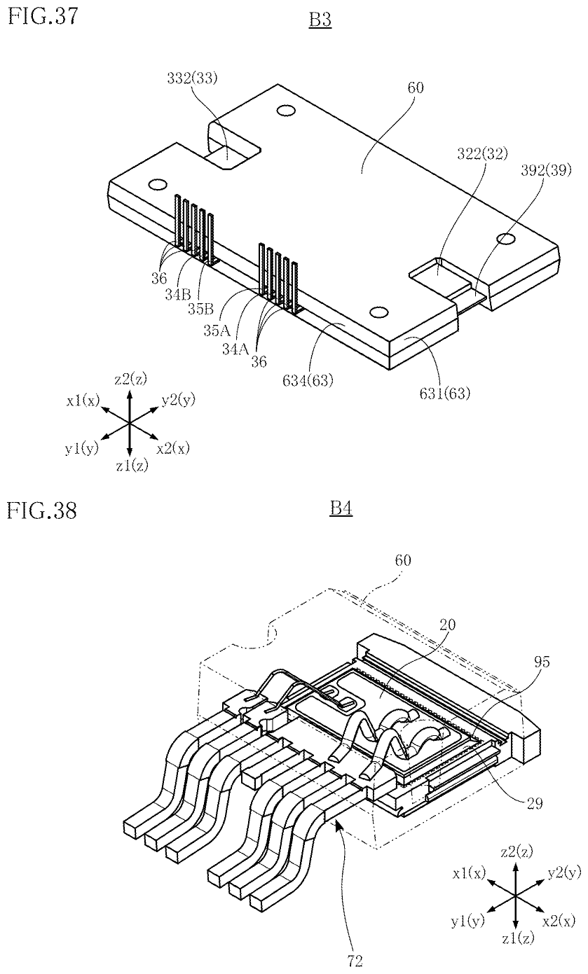

FIG. 37 shows a semiconductor device B3 that differs from the semiconductor device B1 in the shape of the sealing resin 60. With other respects, the semiconductor device B3 is the same as the semiconductor device B1 described above. FIG. 37 is a perspective view of the semiconductor device B3.

In plan view, the sealing resin 60 of this modification has parts extended in the width direction x along the opposite edges in the depth direction y. The part of the sealing resin 60 extended in the width direction x2 covers parts of the input terminals 31 and 32 and of the insulating member 39. Also, the part of the sealing resin 60 extended in the width direction x1 covers a part of the output terminal 33.

The semiconductor device B3 including the bonded structures A1 is less prone to rupturing or peeling of the conductive bonding layers 29, and thus has a higher bonding strength between the switching elements 20 and the conductive members 11. The semiconductor device B3 is therefore enabled to prevent the lowering of electric conductivity and heat dispersion.

The sealing resin 60 of the semiconductor device B3 is larger than that of the semiconductor device B1 and thus covers more regions of the input terminals 31 and 32 and the output terminal 33 and the insulating member 39. The semiconductor device B3 is therefore more reliable than the semiconductor device B1 in protecting the input terminals 31 and 32, the output terminal 33 and the insulating member 39 from deterioration or flexing.

FIG. 38 shows a semiconductor device B4. Unlike the semiconductor device B1, the semiconductor device B4 is a discrete semiconductor and includes a single switching element 20. The semiconductor device B4 may include a semiconductor element such as a diode or an IC instead of the switching element 20.

The semiconductor device B4 is of a lead-frame package type. The semiconductor device B4 includes a lead frame 72. The lead frame 72 may be made of, but not limited to, Cu or a Cu alloy. In addition, the shape of the lead frame 72 is not limited to the example shown in FIG. 38. The switching element 20 is mounted on the lead frame 72. A part of the lead frame 72 and the switching element 20 are covered with the sealing resin 60. The lead frame 72 corresponds to the electrical conductor 92 of the bonded structure A1 described above.

As shown in FIG. 38, the semiconductor device B4 includes the roughened area 95 on the surface of the lead frame 72 on which the switching element 20 is mounted (on the upper surface of the die pad). The conductive bonding layer 29 is disposed on the roughened area 95. That is, the semiconductor device B4 includes the bonded structure A1 formed by the switching element 20 serving as the semiconductor element 91, the lead frame 72 serving as the electrical conductor 92, and the conductive bonding layer 29 serving as the sintered metal layer 93.

The semiconductor device B4 including the bonded structure A1 is less prone to rupturing or peeling of the conductive bonding layer 29, and thus has a higher bonding strength between the switching element 20 and the lead frame 72. The semiconductor device B4 is therefore enabled to prevent the lowering of electric conductivity and heat dispersion.

In the description given above, the semiconductor devices B2 to B4 include the bonded structures A1. Alternatively, however, any of the bonded structures A2 to A5 may be included. In addition, each of the semiconductor devices B1 to B4 may include any of the bonded structures A1 to A5 in combination depending on the corresponding switching elements 20, rather than only one type of the bonded structures A1 to A5.

The bonded structures, the semiconductor devices and the method of forming such a bonded structure according to the present disclosure are not limited to the embodiments described above. Various design changes may be made to the specific configurations of components of the bonded structures and the semiconductor devices according to the present disclosure, and also to the specific processes of the method of forming such a bonded structure according to the present disclosure.

1-21. (canceled)

22. A semiconductor device comprising:
a plurality of semiconductor elements having an element obverse surface and an element reverse surface spaced apart from each other in a first direction, an electrode being formed on each of the element obverse surface and the element reverse surface;
a plurality of electrical conductors, each having a mount surface facing in a same direction as the element obverse surface, the element reverse surface being disposed on the mount surface;
a sintered metal layer that is formed wider than each semiconductor element and conducts the electrode of the element reverse surface of each semiconductor element to a predetermined one of the plurality electrical conductors;
first and second input terminals electrically connected to one of the plurality of semiconductor elements;
an output terminal connected to connection points of the plurality of semiconductor elements serially connected between the respective input terminals; and
a sealing resin sealing at least a part of the first and second input terminals and the output terminal, at least a part of the electrical conductors, and the plurality of semiconductor elements.

23. The semiconductor device according to claim 22,
wherein each semiconductor element is a transistor or a diode composed of SiC.

24. The semiconductor device according to claim 22,
wherein the sintered metal layer includes silver.

25. The semiconductor device according to claim 22,
wherein the sintered metal layer has a fillet covering at least a part of an element side surface of each semiconductor element.

26. The semiconductor device according to claim 22, further comprising a plate-like connecting member electrically connecting the obverse surface electrode of each semiconductor element and one of the plurality of electrical conductors that is electrically conducted to another semiconductor element.

27. The semiconductor device according to claim 22, further comprising an insulating layer disposed on the electrical conductor and gate layers disposed on the insulating layer.

28. The semiconductor device according to claim 22,
wherein the electrical conductor include copper, and the electrical conductor and at least a part of the terminals are laser-welded.

29. The semiconductor device according to claim 28,
wherein the laser welding welds the electrical conductor down to its halfway depth.

30. The semiconductor device according to claim 22,
wherein a roughened area is formed in a region of the electrical conductor where each semiconductor element is disposed.

31. The semiconductor device according to claim 22,
wherein the first and second input terminals are opposed to each other with an insulating member disposed therebetween.

32. The semiconductor device according to claim 31,
wherein a part of the first and second input terminals exposed from the sealing resin is smaller than a part of the insulating member exposed from the sealing resin, and the part of the first and second input terminals and the part of the insulating member are overlapped with one another so as to be separated from their neighbors.

33. The semiconductor device according to claim 30,
wherein the roughened area includes a recess that is recessed in the first direction from the mount surface.

34. The semiconductor device according to claim 33,
wherein the recess includes a plurality of first trenches, the plurality of first trenches as viewed in the first direction extending in a second direction perpendicular to the first direction and arranged next to each other in a third direction perpendicular to the first direction and the second direction,
the plurality of second trenches as viewed in the first direction extending in the third direction and arranged next to each other in the second direction, and
as viewed in the first direction, the plurality of second trenches intersect the plurality of first trenches.

35. The semiconductor device according to claim 34,
wherein the roughened area includes an intersecting portion and a non-intersecting portion, the intersecting portion being constituted by one of the plurality of first trenches and one of the plurality of second trenches overlapped with each other as viewed in the first direction, the non-intersecting portion being constituted by only one trench out of the plurality of first or second trenches as viewed in the first direction, and
a dimension of the intersecting portion in the first direction is greater than a dimension of the non-intersecting portion in the first direction.

36. The semiconductor device according to claim 33,
wherein the recess has finer surface asperities than asperities provided by the recess.

37. The semiconductor device according to claim 22,
wherein the sintered metal layer is made of sintered silver.

38. The semiconductor device according to of claim 22,
wherein the electrical conductor is made of a copper-containing material.

39. A semiconductor device according to claim 22, further comprising:
a first switching element as the semiconductor element;
a first conductive member as the electrical conductor supporting the first switching element; and
a first bonding layer as the sintered metal layer electrically bonding the first switching element and the first conductive member,
wherein the sealing resin covers the first switching element, the first bonding layer and at least a part of the first conductive member.

40. The semiconductor device according to claim 39, further comprising:
a second switching element as one of the plurality of semiconductor elements that is different from the first switching element; and
a second conductive member as one of the plurality of electrical conductors that supports the second switching element,
wherein the first input terminal is electrically connected to the first switching element,
the second input terminal is electrically connected to the second switching element, and
the first input terminal is bonded to the first conductive member and electrically connected to the first switching element via the first conductive member.

41. The semiconductor device according to claim 39,
wherein the first input terminal includes a first terminal portion exposed from the sealing resin,
the second input terminal includes a second terminal portion exposed from the sealing resin,
the output terminal is bonded to the second conductive member and electrically connected to the second switching element via the second conductive member, and
the electrode being formed on obverse surface of the second switching element is electrically connected to the first conductive member.

42. The semiconductor device according to claim 41,
wherein a recess formed in portions of the sealing resin where the first and second terminal portions are exposed, and
the first and second terminal portions are exposed only inside the recess.

43. The semiconductor device according to claim 41, further comprising an insulating member disposed between the first terminal portion and the second terminal portion in the first direction,
wherein the insulating member partially overlaps with the first terminal portion and the second terminal portion as viewed in the first direction, and
the exposed portions of the first and second input terminals extending from the sealing resin are overlapped so as to have an area smaller than an exposed portion of the insulating member, and be spaced apart from a periphery of the exposed portion of the insulating member as viewed in the first direction.
